(19) United States
(12) Patent Application Publication
(10) Pub. No.: US 2016/0118404 A1
(43) Pub. Date: Apr. 28, 2016

(54) THREE-DIMENSIONAL NON-VOLATILE FERROELECTRIC RANDOM ACCESS MEMORY

(71) Applicant: Haibing Peng, Houston, TX (US)

(72) Inventor: Haibing Peng, Houston, TX (US)

(21) Appl. No.: 14/875,744

(22) Filed: Oct. 6, 2015

Related U.S. Application Data
(60) Provisional application No. 62/061,700, filed on Oct. 9, 2014.
(60) Provisional application No. 62/068,739, filed on Oct. 26, 2014.

(51) Int. Cl. H01L 27/115; H01L 29/78; H01L 29/16; H01L 29/51

(52) U.S. Cl. CPC H01L 27/11597; H01L 27/1159; H01L 29/516; H01L 29/78391; H01L 29/517; H01L 29/16; H01L 27/11507; H01L 27/11514

(57) ABSTRACT

The present invention provides a design of three-dimensional non-volatile ferroelectric random access memory (FeRAM) devices for increasing the storage density. The key components include: (1) FeRAM device structures with (i) field-effect-transistors electrically connected either in series or in parallel as a basic memory group and (ii) a double-gate structure for implementing read/write schemes with full random access to individual memory cells, where one type of gates employs ferroelectrics layers as the gate dielectrics while the other type of gates employs conventional dielectric materials as the gate dielectrics; and (2) FeRAM device structures with stacked ferroelectric-capacitors and field-effect-transistors electrically connected in series as a basic NAND memory group. Example fabrication processes for implementing such three-dimensional FeRAM devices are also provided.

### RELATED APPLICATIONS

This application claims the benefit of and priority to (1) U.S. Provisional Patent Application No. 62/061,700, entitled “DESIGN OF THREE-DIMENSIONAL NON-VOLATILE FERROELECTRIC RANDOM ACCESS MEMORY,” filed Oct. 9, 2014; and (2) U.S. Provisional Patent Application No. 62/068,739, entitled “DESIGN OF THREE-DIMENSIONAL NON-VOLATILE FERROELECTRIC RANDOM ACCESS MEMORY,” filed Oct. 26, 2014; the entire content of which are hereby incorporated by reference for all purposes as if set forth herein.

### FIELD OF THE INVENTION

The present invention relates to design of three-dimensional ferroelectric non-volatile memory devices for increasing the storage density. The key components are: 1) the design of stacked device structures for ferroelectric non-volatile memory; 2) the design of double-gate structures for implementing read/write schemes with full random access to individual memory cells, where one type of gates (serving as the Word Line) employs a ferroelectrics layer as gate dielectrics while the other type of gates (serving as the RW Control Line for read/write operations) employs conventional dielectric materials as gate dielectrics; and 3) the fabrication processes to implement such three-dimensional ferroelectric non-volatile memory devices.

### BACKGROUND

Ferroelectric random-access memory (FeRAM) can employ a ferroelectric layer as the gate dielectrics to achieve non-volatility, due to the unique property of ferroelectrics with a hysteresis loop in the polarization response as a function of applied electric field across the ferroelectric layer. The hysteresis response in ferroelectrics leads to two states with different remnant polarization which can be taken as the memory states “1” and “0” in FeRAM. Along with the under-developing spin-transfer-torque MRAM, FeRAM is one of the most promising candidates for high-performance non-volatile memory devices. Besides many functionalities similar to currently widely used floating-gate or charge-trap flash memory (with NAND or NOR logic gates), FeRAM possesses significant advantages over flash memory such as: lower writing voltage, lower power consumption, faster writing speed, and superior wear-proof performance with much larger number of program-erase cycles. However, the storage density in currently available FeRAM is much lower than that of flash memories, making FeRAMs higher cost and thus commercially less competitive in most cases except for certain niche applications. Therefore, it is of significant importance to design FeRAMs with high storage density comparable to flash memory, so that FeRAMs can be competitive in commercial memory markets.

### SUMMARY OF THE INVENTION

The present invention comprises: (1) design of three-dimensional ferroelectric non-volatile memory devices with field-effect-transistors (FETs) electrically connected either in series or in parallel as a basic memory group to achieve high storage densities (theoretically unlimited and practically approaching 1 TB on a center-meter size chip); (2) design of double-gate structures for implementing read/write schemes to address every individual memory cells with full random access for such ferroelectric memory devices, where one type of gates (serving as the Word Line) employs ferroelectrics layers as gate dielectrics while the other type of gates (serving as the RW Control Line for read/write operations) employs conventional dielectric materials as gate dielectrics; (3) design of read schemes with OR-NAND (AND-NOR) logics for the invented ferroelectric memory devices with FETs connected in series (in parallel) as a memory group to address every individual memory cells with full random access; (4) design of three-dimensional ferroelectric non-volatile memory devices with stacked ferroelectric capacitors and FETs electrically connected in series as a basic NAND memory group; (5) design of fabrication processes to implement such three-dimensional ferroelectric non-volatile memory devices.

In terms of terminology, throughout this disclosure, those invented ferroelectric non-volatile memory devices with FETs connected in series as a basic memory group and with a read scheme of OR-NAND logics for full random access to individual memory cells are denoted as “OR-NAND FeRAMs”; those devices with FETs connected in parallel (i.e., sharing the same source and drain electrodes) as a basic memory group and with a read scheme of AND-NOR logics are denoted as “AND-NOR FeRAMs”.

### BRIEF DESCRIPTION OF THE DRAWINGS

FIGS. 1a and 1b show the schematic structures of the basic memory group for vertical OR-NAND FeRAM devices according to the present invention. A vertical poly-silicon post (or other conducting semiconductor post) serves as the conduction path for FETs vertically connected in series in the memory group; the left-side gates employ a ferroelectric layer (e.g. lead zirconate titanate PZT) in contact with the conduction channel as the gate dielectrics and each stacked left gate (e.g., a conducting poly-silicon layer) serves as the Word Line for an individual memory cell (i.e., one FET); the corresponding right-side gate employs conventional dielectrics (e.g. HfO₂, SiO₂, or a depolarized ferroelectric layer with no hysteresis in polarization response) as gate dielectrics and serves as the RW Control Line for Read/Write operations. The top of the conduction channel (poly-silicon post) is connected as the Bit Line and its bottom is connected as the Source Line (ground) of the memory group.

FIGS. 2a-2g present schematic structures of the basic memory group for planar OR-NAND FeRAM devices with double-gate structure for implementing a read/write scheme with full random access, where one type of gate employs ferroelectrics and the other type uses conventional dielectrics.

FIGS. 3a-3e show schematic diagrams of an example fabrication process for implementing a vertical OR-NAND FeRAM device with arrays of basic memory groups according to the present invention. The top view (upper panel) and cross-sectional view (lower panel) of the device at different fabrication stages are presented. During the fabrication process, the width of the PZT segment to the right side of the semiconductor channel is designed to be less than a critical dimension, so that the depolarization effect due to the finite size of the corresponding PZT segment is able to cause a loss (or significant degrading) of hysteresis loop in the polarization response, and thus this PZT segment behaves effectively as a conventional dielectrics without appreciable remnant polarization.

FIGS. 4a-4d show schematic diagrams of extra fabrication steps proposed for an alternative implementation of the proposed vertical OR-NAND FeRAM device according to the present invention. Here a conventional dielectric material such as SiO₂ is used as the gate dielectrics for the right-side gate (the RW Control Line).

FIGS. 5a-5c show a top view, a cross-sectional view from back (indicated by arrow), and a cross-sectional view from side (indicated by arrow), respectively, of a basic memory group for a vertical AND-NOR FeRAM device with FETs electrically connected in parallel (i.e., sharing the same source and drain electrodes).

FIGS. 6a-6c show a top view, a cross-sectional view from back (indicated by arrow), and a cross-sectional view from side (indicated by arrow), respectively, of a basic memory group for an alternative design of vertical AND-NOR FeRAM devices.

FIGS. 7a-7c show a top view, a cross-sectional view from back (indicated by arrow), and a cross-sectional view from side (indicated by arrow), respectively, for a planar AND-NOR FeRAM device consisting of arrays of planar basic memory group with FETs electrically connected in parallel (i.e., sharing the same source and drain electrodes).

FIGS. 8a-8c show a top view, a cross-sectional view from back (indicated by arrow), and a cross-sectional view from side (indicated by arrow), respectively, for an alternative design of planar AND-NOR FeRAM device consisting of arrays of planar basic memory group with FETs electrically connected in parallel (i.e., sharing the same source and drain electrodes). Here the silicon segments between adjacent parallel conduction channels are etched away and filled with insulating dielectrics.

FIGS. 9a-9b show a top view and a cross-sectional view from back (indicated by arrow) for two alternative planar basic AND-NOR memory groups with FETs electrically connected in parallel (i.e., sharing the same source and drain electrodes).

FIGS. 10a-10d show schematic diagrams of an example fabrication process for implementing a vertical AND-NOR FeRAM device with arrays of basic memory groups according to the present invention. The top view (upper panel) and cross-sectional view (lower panel) of the device at different fabrication stages are presented. During the fabrication process, the width of the PZT segment to the right side of the semiconductor channel is designed to be less than a critical dimension, so that the depolarization effect due to the finite size of the corresponding PZT segment is able to cause a loss (or significant degrading) of hysteresis loop in the polarization response, and thus this PZT segment behaves effectively as a conventional dielectrics without appreciable remnant polarization.

FIG. 11 shows the schematic structure of a basic NAND memory group consisting of pairs of FET and ferroelectric-capacitor which are electrically connected in series vertically (or along a direction out of the plane of the substrate).

FIGS. 12a-12g show schematic diagrams of an example fabrication process for implementing arrays of the basic NAND memory group of FIG. 11 to form three-dimensional transistor-capacitor type NAND FeRAM devices.

FIGS. 13a-13c show a top view, a cross-sectional view from back (indicated by arrow), and a cross-sectional view from side (indicated by arrow), respectively, for a basic NAND memory group consisting of pairs of FET and ferroelectric-capacitor which are electrically connected in series along a direction parallel to the plane of the substrate.

FIG. 14 show a top view and a cross-sectional view from back (indicated by arrow) for another planar basic NAND memory group consisting of pairs of FET and ferroelectric-capacitor which are electrically connected in series along a direction parallel to the plane of the substrate. Here bottom gates are used for FETs and ferroelectric capacitors are located on top of the conduction channel.

FIG. 15 show a top view and a cross-sectional view from back (indicated by arrow) for another planar basic NAND memory group consisting of pairs of FET and ferroelectric-capacitor which are electrically connected in series along a direction parallel to the plane of the substrate. Here top gates are used and ferroelectric capacitors are located below the conduction channel.

### DETAILED DESCRIPTION OF THE INVENTION

The present invention provides a design of three-dimensional ferroelectric non-volatile memory devices for increasing the storage density. The key components are: 1) design of vertical and planar OR-NAND FeRAMs with FETs connected in series as a basic memory group and a read/write scheme with full random access to individual memory cells; 2) design of vertical and planar AND-NOR FeRAMs with FETs connected in parallel as a basic memory group and a read/write scheme with full random access to individual memory cells; 3) design of double-gate structure for implementing read/write schemes for the proposed OR-NAND FeRAMs and AND-NOR FeRAMs, where one type of gates (serving as the Word Line) employs ferroelectrics layers as gate dielectrics while the other type of gates (serving as the RW Control Line for read/write operations) employs conventional dielectric materials as gate dielectrics; (4) design of three-dimensional transistor-capacitor type NAND FeRAMs with stacked ferroelectric capacitors and FETs electrically connected in series as a basic memory group; and 5) some example fabrication processes to implement the proposed OR-NAND and AND-NOR FeRAM devices, and the three-dimensional transistor-capacitor type NAND FeRAM device. Details of the OR-NAND FeRAMs, the AND-NOR FeRAMs, and the three-dimensional transistor-capacitor type NAND FeRAMs are described below in three separate sections, respectively.

OR-NAND FeRAMs with FETs Connected in Series as a Basic Memory Group and a Read Scheme of OR-NAND Logics for Full Random Access to Individual Memory Cells

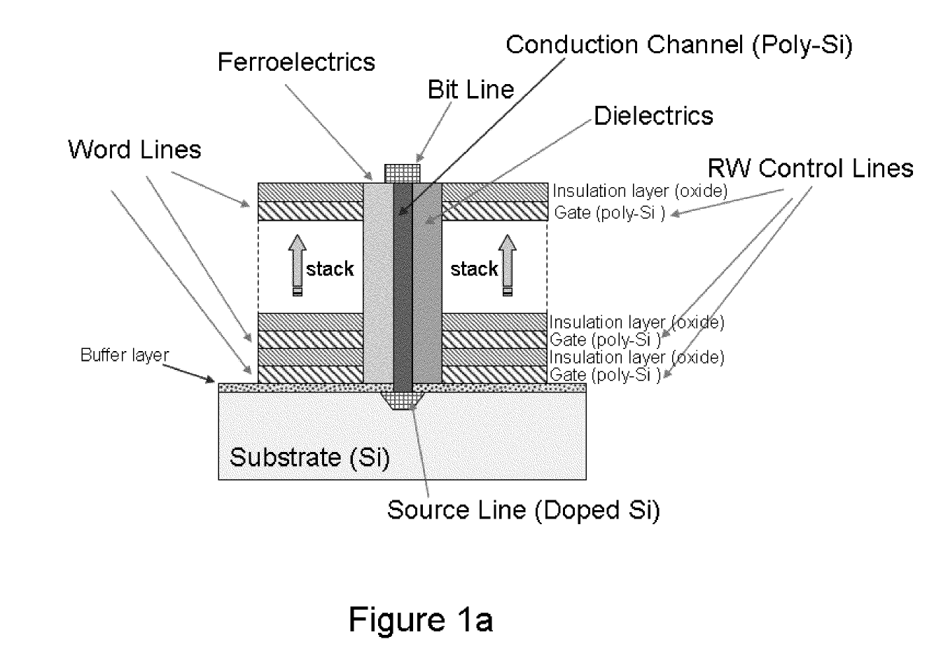

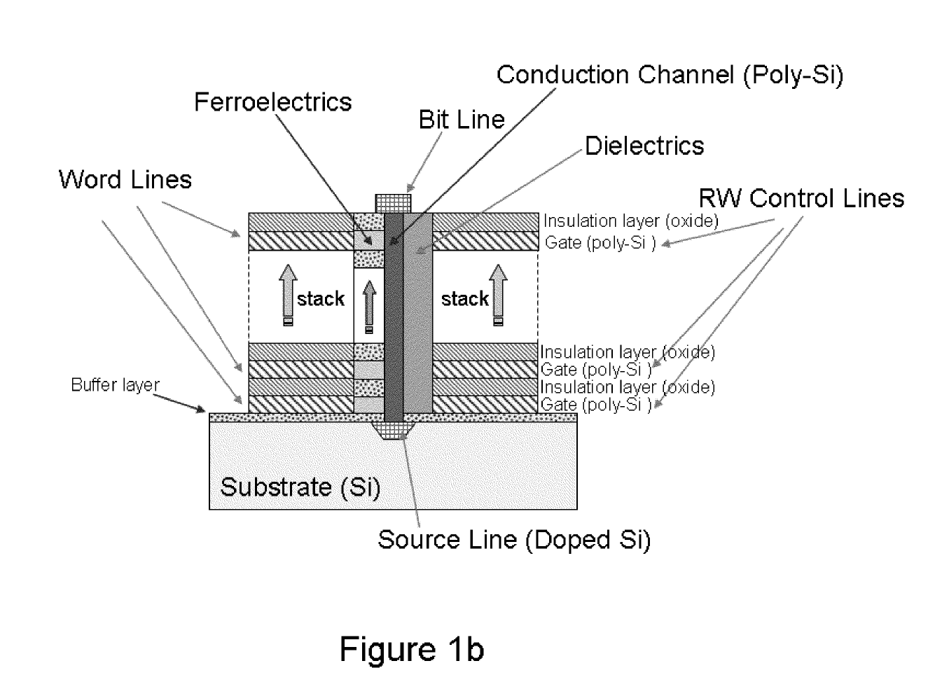

In one embodiment, the present invention comprises a design of vertical OR-NAND FeRAM devices with a basic memory group consisting of FETs connected in series vertically, as illustrated in FIG. 1a. Such basic memory groups will be produced and connected in arrays on chip to form non-volatile three-dimensional ferroelectric memories: OR-NAND FeRAMs. In the present invention (FIG. 1), a vertical poly-silicon post (or post of other semiconductors including Ge and Si) serves as the conduction path for FETs vertically connected in series; the left-side gate employs a ferroelectric layer (e.g. lead zirconate titanate PZT, BaTiO₃, Ba₁₋ₓSrₓTiO₃ or BiFeO₃) in contact with the conduction channel as the gate dielectrics and each stacked left gate (e.g. a conducting poly-silicon layer, a conducting SrRuO₃ layer, or a metal layer such as Pt) serves as the Word Line for an individual memory cell (i.e., one FET); the corresponding right-side gate employs conventional dielectrics (e.g. HfO₂, SiO₂, Al₂O₃, ZrO₂, or a thinner depolarized ferroelectric layer with no hysteresis in polarization response) as gate dielectrics and serves as the RW Control Line for Read/Write operations (to be described later). In an alternative configuration, a thin insulator layer (e.g., silicon nitride, HfO₂, Al₂O₃, SiO₂, or ZrO₂ thin film with a preferred thickness from one atomic layer to ˜10 nm) can be sandwiched between the ferroelectric layer and the conduction channel (poly-Si post) and/or sandwiched between the ferroelectric layer and the side wall of the gate, which may be useful for increasing the retention time of remnant polarization in the ferroelectric layer. To function as OR-NAND FeRAM devices, each stacked left-gate (e.g., conducting poly-silicon layer) is connected to a Word Line for the memory device, the top of the vertical conduction channel (poly-silicon post) is connected to a Bit Line and its bottom is connected to the Source Line (ground) via a degenerately doped silicon region on the substrate. In the case that an accumulation layer is used for electrical conduction in the FET ON state, one preferred material configuration is: a p-doped or n-doped poly-Si (or Si) post as the conduction channel and degenerately doped Si regions (with the same doping type as the conduction channel) as the contacts for Source Line and Bit Line. The number of individual memory cell (i.e., FET) along a single vertical conduction path (poly-silicon post) is determined by the number of layers of alternating layered insulation/gate (e.g. oxide/poly-silicon) stacks, and therefore determines the storage density of the three-dimensional OR-NAND FeRAMs. In addition, a plurality of basic vertical memory groups shown in FIG. 1 can be connected in series to form a larger OR-NAND memory group. On the chip level, these OR-NAND memory groups can be connected via additional FETs to form Bit/Source Line arrays for the purpose of addressing every OR-NAND memory group.

In an alternative configuration of the basic memory group (FIG. 1b) for vertical OR-NAND FeRAM devices, the continuous ferroelectric layer of FIG. 1a can be replaced by a stack of ferroelectrics/buffer layers in accordance with the gate stack for all FETs vertically connected in series. The buffer layer can be made of insulators such as SrTiO₃ or MgO.

In an alternative embodiment of the present invention, for the basic OR-NAND memory group of FIGS. 1a and 1b, the right-side gate (with conventional gate dielectrics) of the top most FET in the stack can function as a Bit Selection Line to disconnect or connect the basic OR-NAND group from the Bit Line, and the right-side gate of the bottom most FET in the stack can function as a Source Selection Line to disconnect or connect the basic OR-NAND group from the Source Line during read/write operations.

In another embodiment, the present invention comprises a design of double-gate structure for implementing a read/write scheme with full random access to individual memory cells, where one type of gates (serving as the Word Line) employs ferroelectrics layers as gate dielectrics while the other type of gates (serving as the RW Control Line for read/write operations) employs conventional dielectric materials as gate dielectrics. For example, to read the state of a specific individual memory cell (FET), the following scheme can be used: first, the desired memory group shown in FIG. 1 (or a larger group) containing the target memory cell is selected (i.e., the bottom source electrode of the selected group is electrically connected to a grounded common Source Line and the top drain electrode of the group is electrically connected to a common Bit Line), and all Word Lines of the selected memory group are kept floating or grounded (so that the corresponding ferroelectric segments are kept in its existing memory states with remnant polarization undisturbed); next, all RW control lines in the selected memory group except for the one connected to the target memory cell are set at a voltage level Vₒₙ (so that the corresponding FET are turned on regardless of the remnant polarization of the ferroelectric segment of corresponding left-side gate—Word Line) and the RW Control Line of the target memory cell to read is set at a suitable control voltage level V_{read} (e.g., near the threshold gate voltage of the corresponding FET where the transconductance is maximized) where the state of the corresponding FET is purely determined by the remnant polarization of the ferroelectric segment (i.e., the FET is turned on in one state of the remnant polarization, but turned off in the other state with reversed remnant polarization); finally, the output voltage signal at the Bit Line of the selected group is read to provide information on the state of the target memory cell (if the target cell is in a state with a remnant polarization being able to turn on the associated FET, the Bit Line will be pulled low to the state “0”; otherwise, the Bit Line will stay high at the state “1”), and then the memory group is deselected (i.e. the source and drain electrodes of the group are floated and the Word Lines and RW control lines are reset to appropriate levels, e.g., floating or grounded, to keep the remnant polarization states undisturbed). The presented read scheme is best described as a combined “OR-NAND” logic operation: an OR operation is first performed on a pair of the memory state (remnant polarization of gate ferroelectrics) and the control state at the corresponding dielectric gate (RW Control Line) for every memory cell in the same memory group; and then the outputs of all those OR operations go through a NAND operation to determine the state of the Bit Line.

In an alternative read scheme, instead of reading the output voltage signal at the Bit Line of the selected group in the final reading step (as previously described), one can also monitor the electrical current flow from the Bit Line to the Source Line via a sense amplifier to provide information on the state of the target memory cell. Since a remnant polarization is able to modulate the current flow of the associated FET for the target cell, there should be a larger electrical current flow from the Bit Line to the Source Line in one state; while such an electrical current flow will be smaller in another remnant polarization state. This reading scheme may be more sensitive than the previous reading scheme, if the remnant polarization is not able to turn the associated FET completely on or off even when the control voltage level V_{read} is optimally set near the threshold gate voltage of the corresponding FET where the transconductance is maximized.

An additional advantage of the design is that writing can be done either on just one individual memory cell, or in parallel on any number of selected memory cells in a group. To program the state of a specific individual memory cell (FET), the following scheme can be used: first, the desired memory group containing the target memory cell is selected (i.e., the bottom source electrode of the selected group is electrically connected to a grounded common Source Line and the top drain electrode of the group is electrically connected to a grounded common Bit Line), and all Word Lines of the selected memory group are kept floating or grounded (so that the corresponding ferroelectric segments are kept in its existing memory states with remnant polarization undisturbed); next, all RW control lines in the selected memory group are set at the voltage level Vₒₙ so that all FETs in the group are turned on and the vertical conduction channel is at the same electrostatic potential (i.e. grounded); after that, the Word Line of the target memory cell is set at a desired writing voltage level V_{write} for a short period of time to apply an electric field (with amplitude greater than the coercive field of the ferroelectrics) across the ferroelectric layer and thus program the remnant polarization state of the ferroelectric segment as desired; finally, the memory group is deselected (i.e. the source and drain electrodes of the group are floated and the Word Lines and RW control lines are reset to appropriate levels, e.g., floating or grounded, to keep the remnant polarization states undisturbed). To program a plurality of selected memory cells in a group in parallel, the only difference lies in the second last step for writing, where the Word Lines of all target memory cells are set at the desired writing voltage level V_{write} simultaneously to program the remnant polarization states. This parallel writing process provides significant advantage in further boosting the writing speed, which will be useful for periodically refreshing stored information in FeRAMs if necessary.

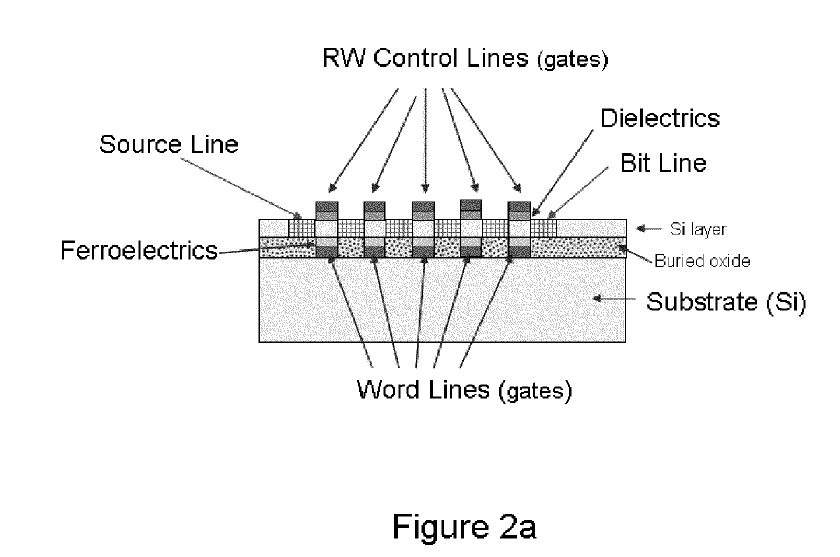

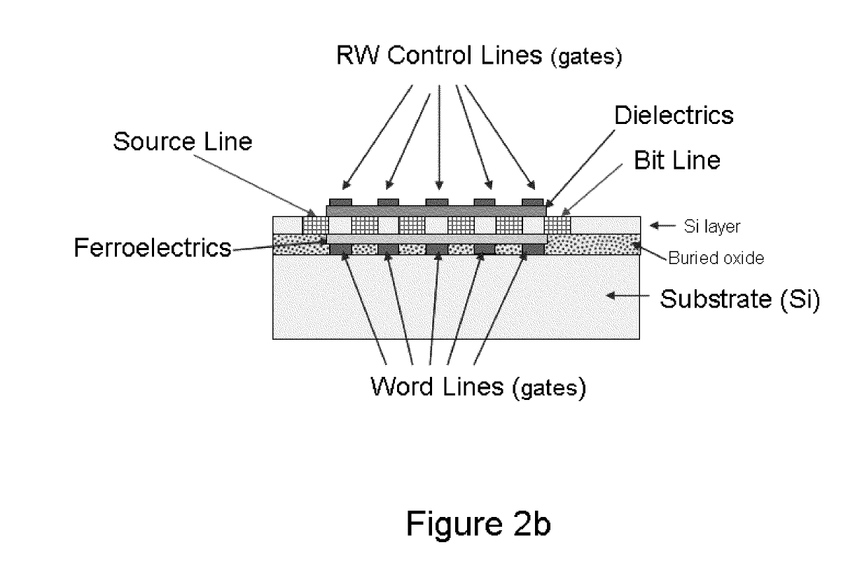

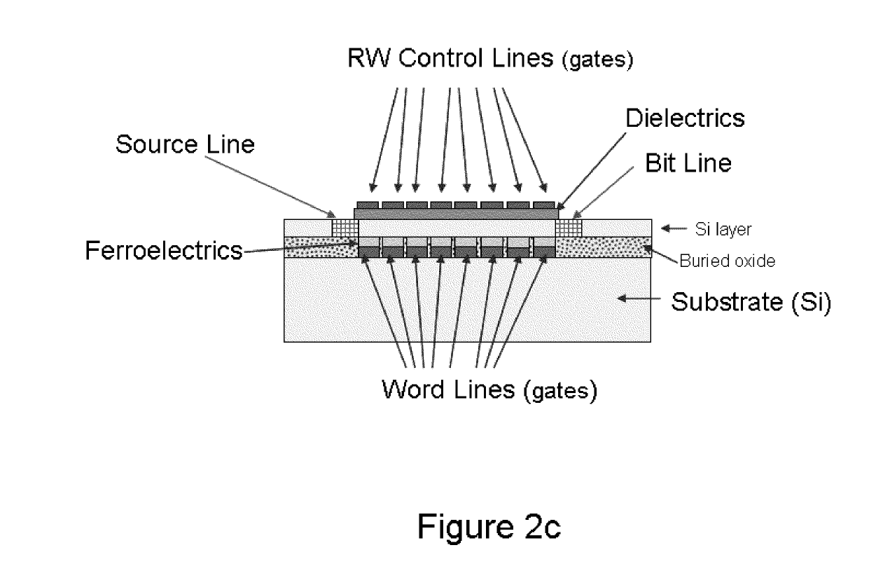

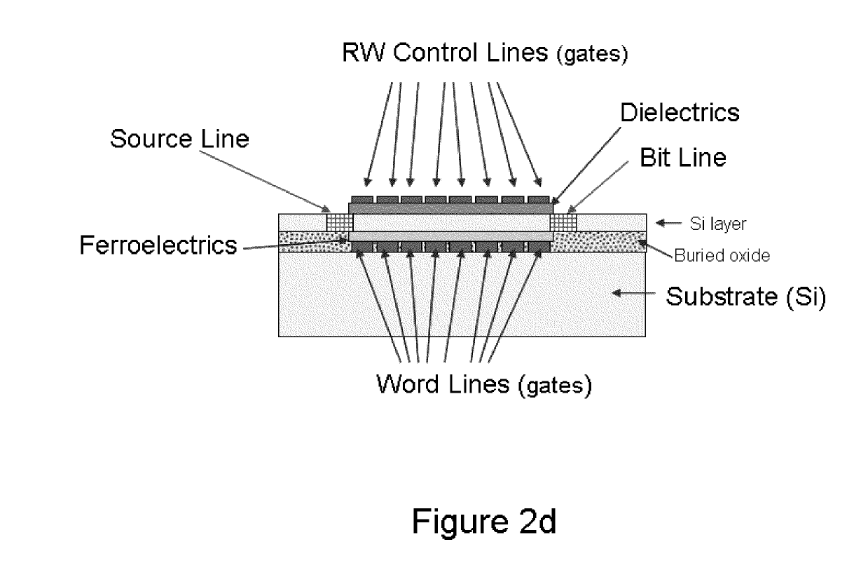

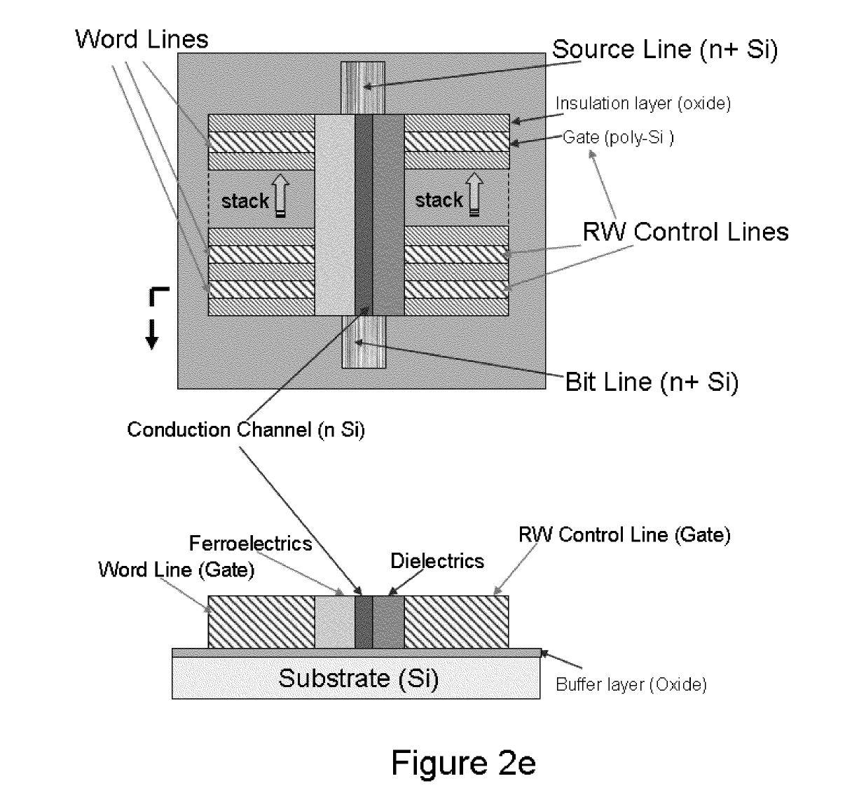

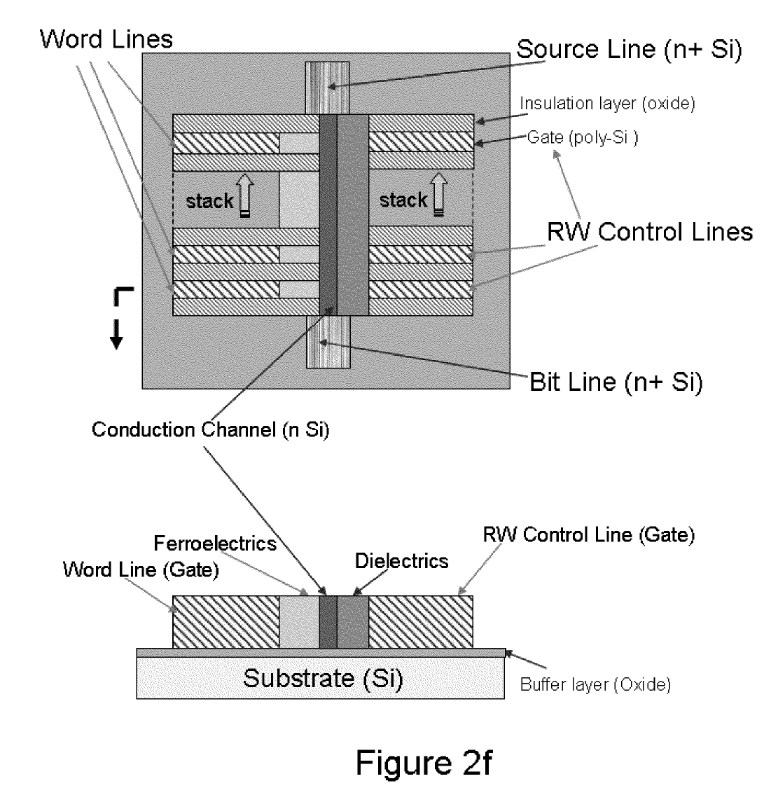

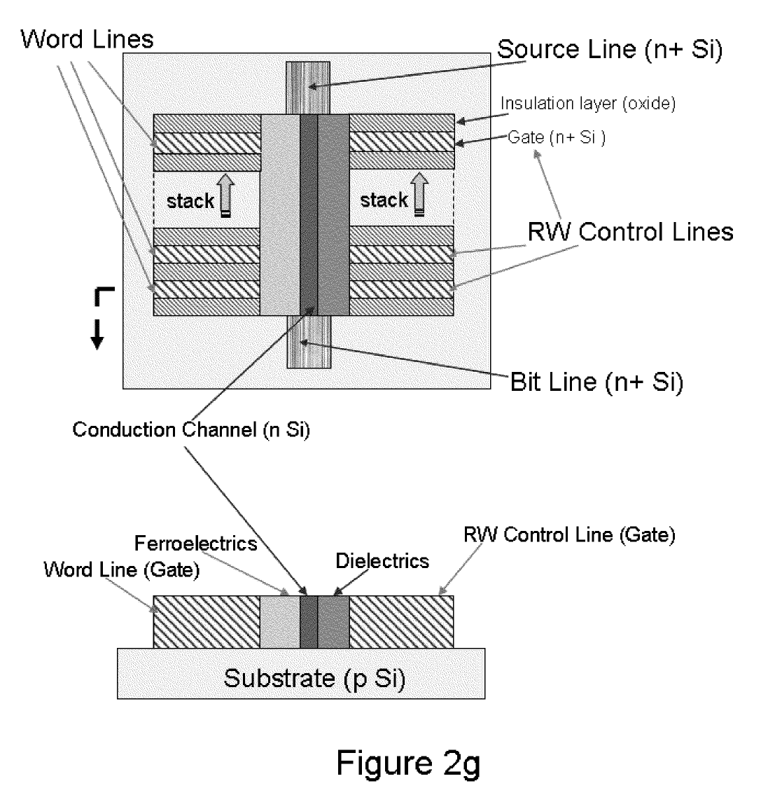

In an alternative embodiment of the invention, the aforementioned read/write scheme for memory devices with double-gate structure can also be implemented in planar OR-NAND FeRAM devices with FETs connected in series. Four example designs are shown in FIGS. 2a-2d, respectively, where a bottom gate (serving as the Word Line) employs ferroelectrics layers as gate dielectrics while a top gate (serving as the RW Control Line for read/write operations) employs conventional dielectric materials as gate dielectrics. In an alternative configuration of the bottom gate, a thin insulator layer (e.g., silicon nitride, HfO₂, Al₂O₃, SiO₂, or ZrO₂ thin film with a preferred thickness from one atomic layer to ˜10 nm) can be sandwiched between the ferroelectric layer and the conduction channel (Si layer), which may be useful for increasing the retention time of the remnant polarization in the ferroelectric layer. For the planar ferroelectric memory groups shown in FIG. 2, the number of FETs connected in series can be varied. In the case that an inversion layer is used for electrical conduction in the FET ON state, the preferred material configuration for the conduction channel include: (1) p-doped Si layer with the source/drain segments for all FETs degenerately n-doped; (2) n-doped Si layer with the source/drain segments for all FETs degenerately p-doped; and (3) a uniformly p-doped (n-doped) Si layer with only two ends of the channel (Source Line and Bit Line) degenerately n-doped (p-doped). The third configuration mentioned above is useful only when the separation between adjacent gates of the FETs connected in series is less than a critical length (e.g., ˜10 nm or less) so that stray electric fields of neighboring gates are able to tune the source/drain segments connecting adjacent FETs into inversion layers. In the case that an accumulation layer is used for electrical conduction in the FET ON state, the preferred material configuration for the conduction channel include: (1) a uniformly p-doped or n-doped Si layer with only two ends of the channel (Source Line and Bit Line) degenerately doped with the same type of carrier as the channel; (2) a p-doped or n-doped Si layer with the source/drain segments for all FETs degenerately doped with the same type of carrier as the channel. For all designs of FIG. 2, the preferred thickness of the Si layer is from 1 nm to 50 nm, but can be varied as long as the FETs are operational to realize the OR-NAND read scheme. Alternatively, material candidates of the conduction channel can be other forms of Si, thin film or few atomic-layers of semiconductors (such as Ge, MoS₂, WS₂, SnS₂ and other semiconducting metal-chalcogenides compounds), and single or multilayer graphene. The preferred material candidates of the bottom gate (Word Line) include conductors such as Nb doped SrTiO₃ , SrRuO₃, or Pt, which can facilitate the growth of better quality ferroelectric layer (e.g., PZT, BaTiO₃, Ba₁₋ₓSrₓTiO₃ or BiFeO₃) on top. The preferred material candidates for the conventional dielectrics of the top gate include SiO₂ and high-K dielectrics such as HfO₂, Al₂O₃, or ZrO₂ (e.g., prepared by ALD). In addition, the relative positions of the ferroelectric gate and the conventional dielectric gate can be adjusted in modified versions of planar ferroelectric memory devices, as long as a read/write scheme with full random access to all individual memory cells can be realized with two types of gates. For example, for the planar basic memory groups of FIGS. 2a-2d, the ferroelectric gate can be changed to the top position with the conventional dielectric gate on the bottom. Alternatively, side gates can be configured as shown in the basic planar memory group of FIGS. 2e and 2f, for which the preferred material configurations for the conduction channel are the same as what were described above for the planar OR-NAND memory groups of FIGS. 2a-2d. Alternatively, the planar OR-NAND memory groups of FIGS. 2e and 2f with side gates can also be fabricated on bulk silicon wafers, where the conduction channel (silicon fin) is implemented via etching into a Si wafer, as shown by one example design in FIG. 2g. Here one can start with a p-doped (n-doped) Si wafer with the conduction channel n-doped (p-doped) and the source/drain degenerately n-doped (p-doped) to avoid leakage current flow through the substrate. In summary, such basic planar OR-NAND memory groups of FIG. 2 can be produced and connected in arrays on chip (along directions either within the substrate plane or out of the substrate plane via layer-by-layer stacking) to form non-volatile three-dimensional OR-NAND FeRAM devices.

In certain embodiment of the invention, the double-gate structure for implementing a read/write scheme with full random access to all individual memory cells can also comprise one type of gates using other phase-change materials to replace the ferroelectric layer as the storage medium. Also, the second type of gates with conventional dielectrics (RW Control Line) can be replaced with a mechanical switch (e.g. a micro-/nano-electromechanical switch) as the control to short the conduction channel segment of the corresponding memory cell for the purpose of read/write operations.

In alternative embodiments of the invention, the gate structure for implementing a read/write scheme with full random access to all individual memory cells can also comprise one group of gates using phase-change materials (such as ferroelectrics) as the storage medium for a single FET, and the second group of gates as the control for the purpose of read/write operations. The specific number of gates in each group for a single FET can be varied.

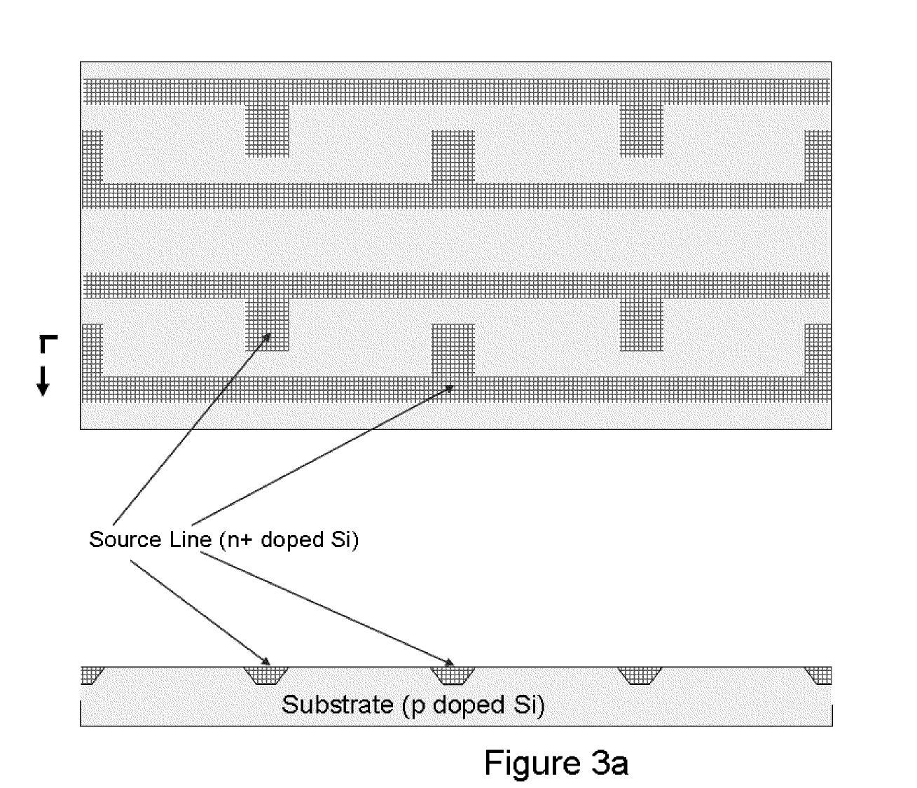

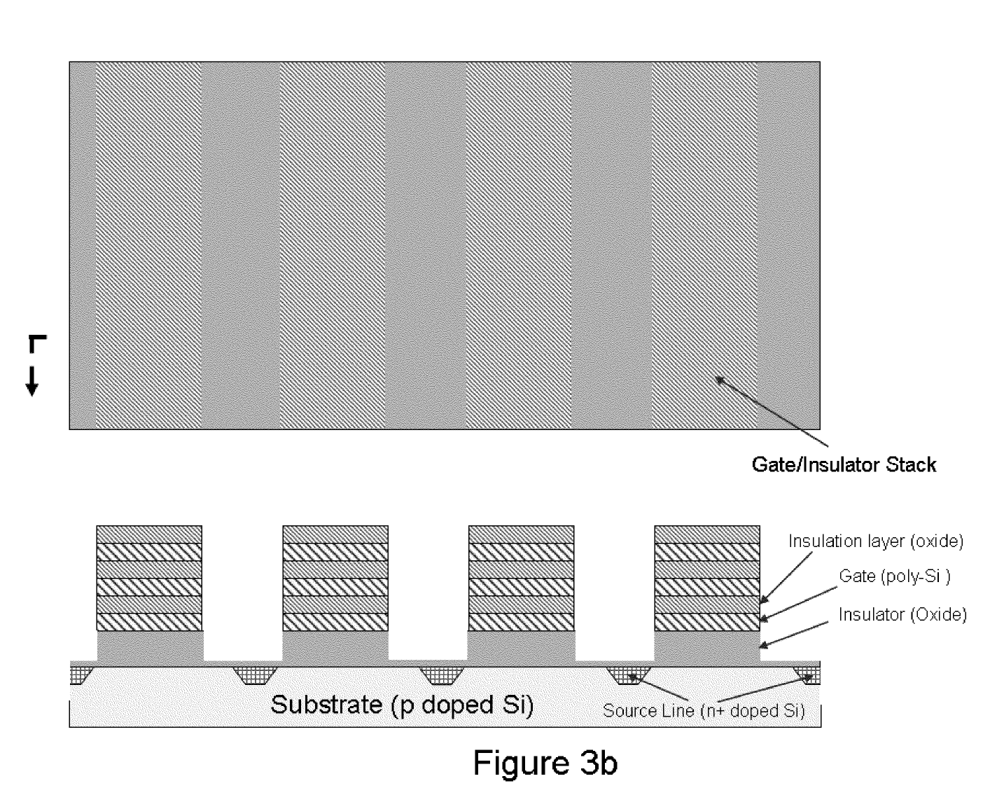

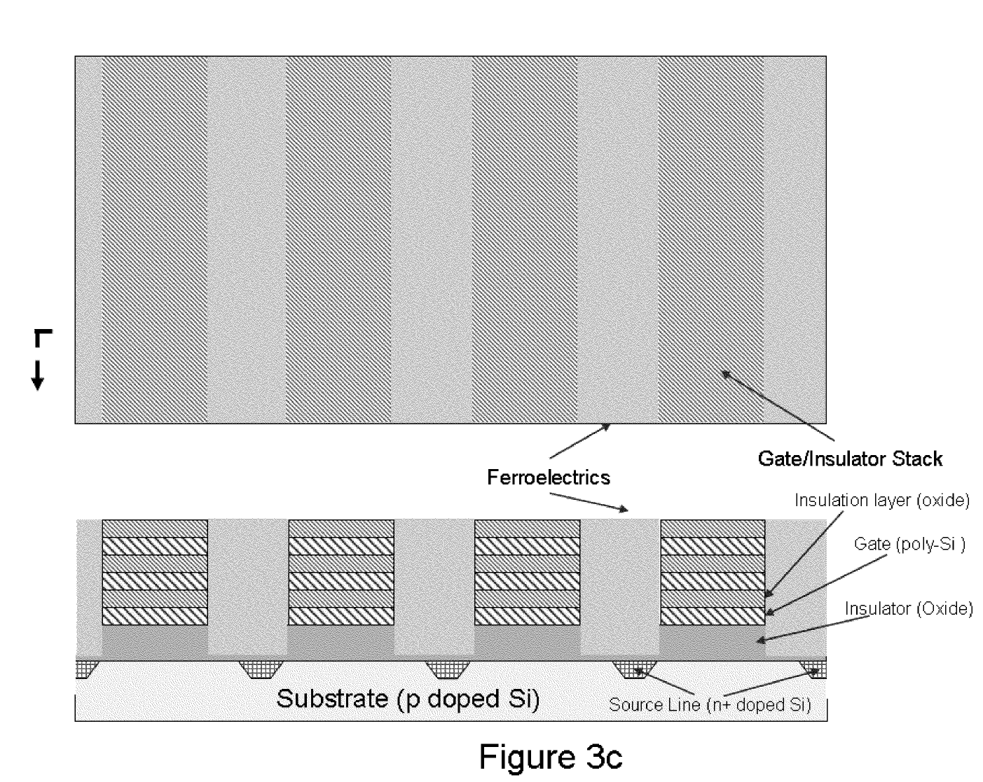

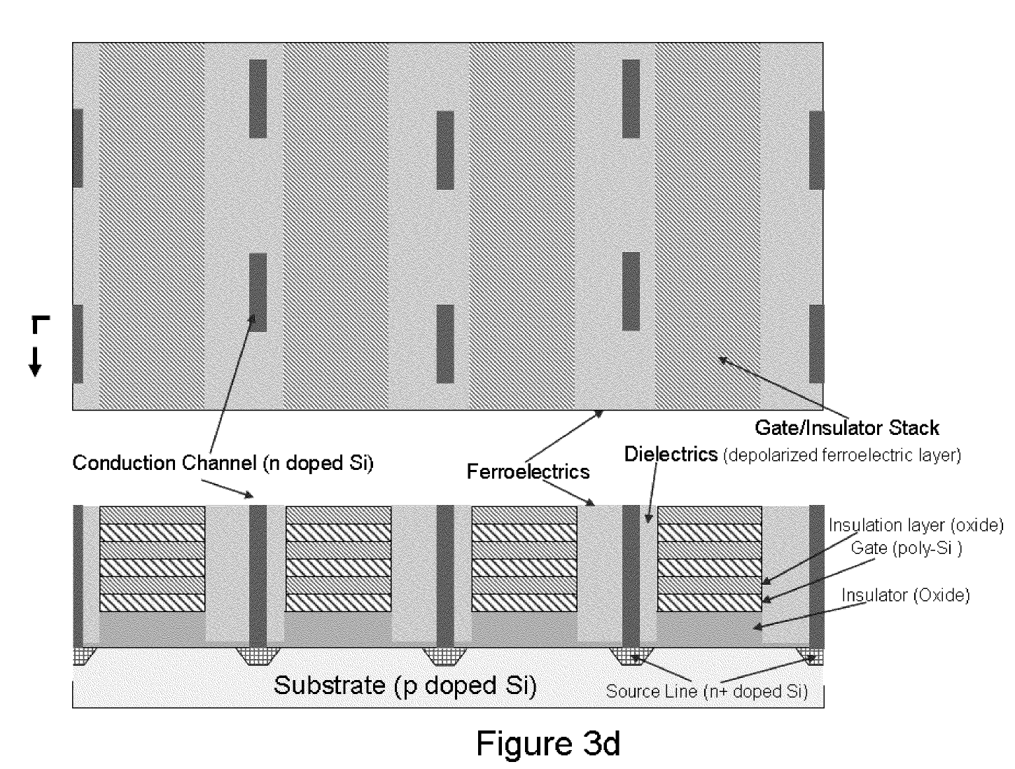

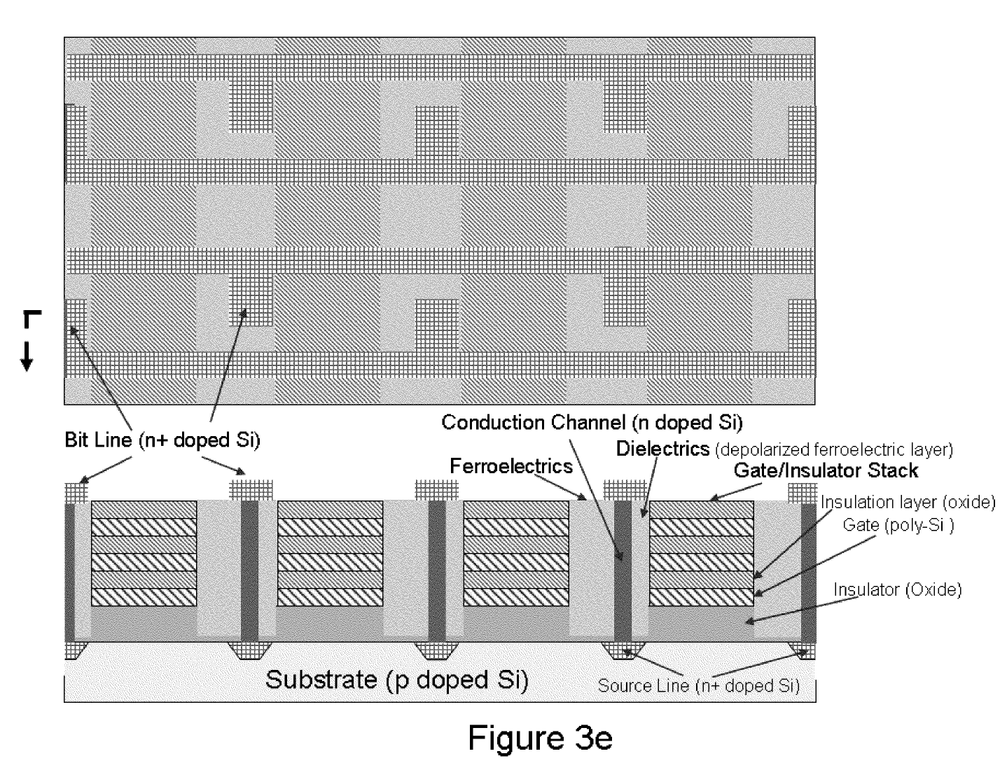

In some embodiments, the present invention comprises device fabrication methods for implementing arrays of the basic vertical memory group of FIG. 1a to form three-dimensional OR-NAND FeRAM devices. One example of detailed device fabrication process is illustrated in FIG. 3. First, arrays of degenerately doped pads are produced and connected on a silicon substrate to form rows of Source Lines (FIG. 3a), e.g., via ion implantation with a masked pattern. Next, an insulator layer of SiO₂ (or other insulator) typically in the order of 100 nm thick is deposited on the Si wafer, followed by a blanket deposition of a stack of alternating gate/insulation layers. In one example, the gate layer can be a heavily doped poly-Si prepared by LPCVD, and the insulation layer can be SiO₂ prepared by LPCVD. In an alternative example, the gate layer can be a conducting layer (e.g. TiN or metals) prepared by atomic layer deposition (ALD), and the insulation layer can be HfO₂, Al₂O₃, or ZrO₂ prepared by ALD. The thickness of the gate and insulation layers can be varied depending on the desired storage density and the performance, although typical thickness of the gate layer can be from 10 nm to 500 nm and the insulation layer should be sufficiently thick (e.g., >30 nm in some embodiments) to suppress interference between neighboring memory cells during operations. After that, the gate/insulation multilayer stack is etched into stripes as shown in FIG. 3b, via techniques such as masked ion-milling, or other dry etching and wet etching methods. Subsequently, as shown in FIG. 3c, a ferroelectric layer is grown on the substrate (with the leftover SiO₂ as buffer layer) via thin film techniques such as physical vapor deposition (e.g., thermal evaporation, sputtering, pulsed laser ablation, and etc.), chemical vapor deposition, atomic lay deposition (ALD), Sol-Gel method, chemical solution deposition method, or other chemical reaction methods. Alternatively, one can grow another buffer layer before the deposition of the ferroelectrics to facilitate the growth of high-quality ferroelectric layers on top. The material candidates of the buffer layer include silicon dioxide, MgO, and SrTiO3; and the thickness of the buffer layer is preferred to be in a range of ˜1 nm to ˜500 nm but in general can be ranging from a single atomic layer to a few microns. The material candidates of ferroelectrics include lead zirconate titanate (PZT), BaTiO₃, Ba₁₋ₓSrₓTiO₃ and BiFeO3, or organic ferroelectrics such as P(VDF-TrFE), or ferroelectrics such as doped hafnium oxide (e.g., doped with Yttrium, Zr or Si); and the thickness of the ferroelectric layer depends on the number of memory cells (FETs) that will be designed for a vertical OR-NAND memory group shown in FIG. 1. After that, arrays of holes will be etched all the way through the ferroelectric layer (taking PZT as a specific example material) and the buffer layer, and then filled with a semiconducting material (e.g. poly-Si, Epi-Si, or Ge in specific cases) as the conduction channel for FETs (FIG. 3d). The width of the holes is preferably from ˜1 nm to ˜100 nm although it can be varied depending on the device performance, and the length of the holes is preferably from a few nanometers to ˜1 μm but this dimension can be varied further depending on the desired area density of memory arrays. The etching of hole arrays can be preferably done with masked ion-milling, or other dry etching or wet etching methods. The holes can be filled with poly-Si (via techniques such as LPCVD) or Epi-Si (via techniques such as CVD) as the semiconductor channel for FETs. One preferred configuration for the semiconductor channel is a poly-Si (or Epi-Si) post uniformly doped with the same type of carrier as the aforementioned degenerately-doped pad (Source Line) on the Si substrate, so that when all FETs in series are turned on electrical conduction can go through accumulation layers in the conduction channel for each FET and also through all source/drain segments electrically connecting adjacent FETs. Other configurations of the doping profile of the whole conduction channel (poly-Si or Epi-Si post) can also be adopted following what was discussed previously on the conduction channel for the planar memory devices of FIG. 2. It is worthwhile to note particularly that in this design (FIG. 3d), the PZT (ferroelectrics) section to the left side of the semiconductor channel is wider so that its ferroelectric properties with remnant polarization is maintained to serve as the storage medium. However, the width of the PZT section to the right side of the semiconductor channel is designed to be less than a critical dimension so that the depolarization effect due to the finite size of the corresponding PZT section is able to cause a loss (or significant degrading) of hysteresis loops in the polarization response as a function of applied electric field, i.e. it behaves effectively as a conventional dielectrics without appreciable remnant polarization. This depolarized PZT section in the right is critical for implementing the right-side gate as the RW Control Line outlined in FIG. 1. In the end, the memory device is finalized (FIG. 3e) after the preparation of electrodes for Bit Lines (Rows), Source Lines (Rows) and Word Lines/RW Control Lines (stacked gates in columns).

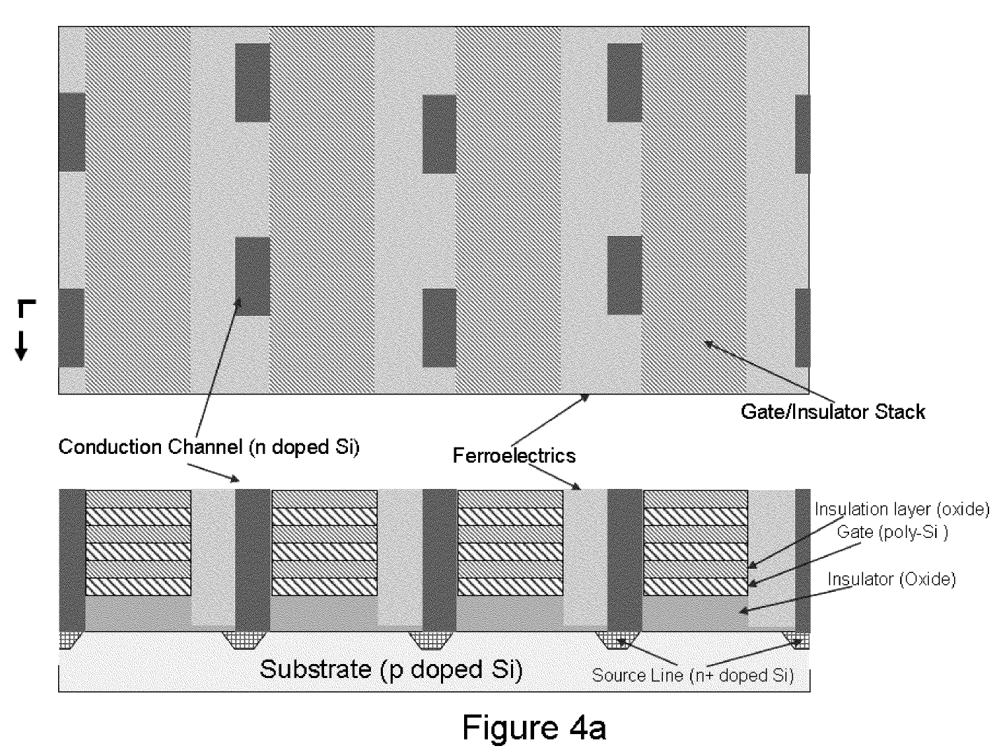

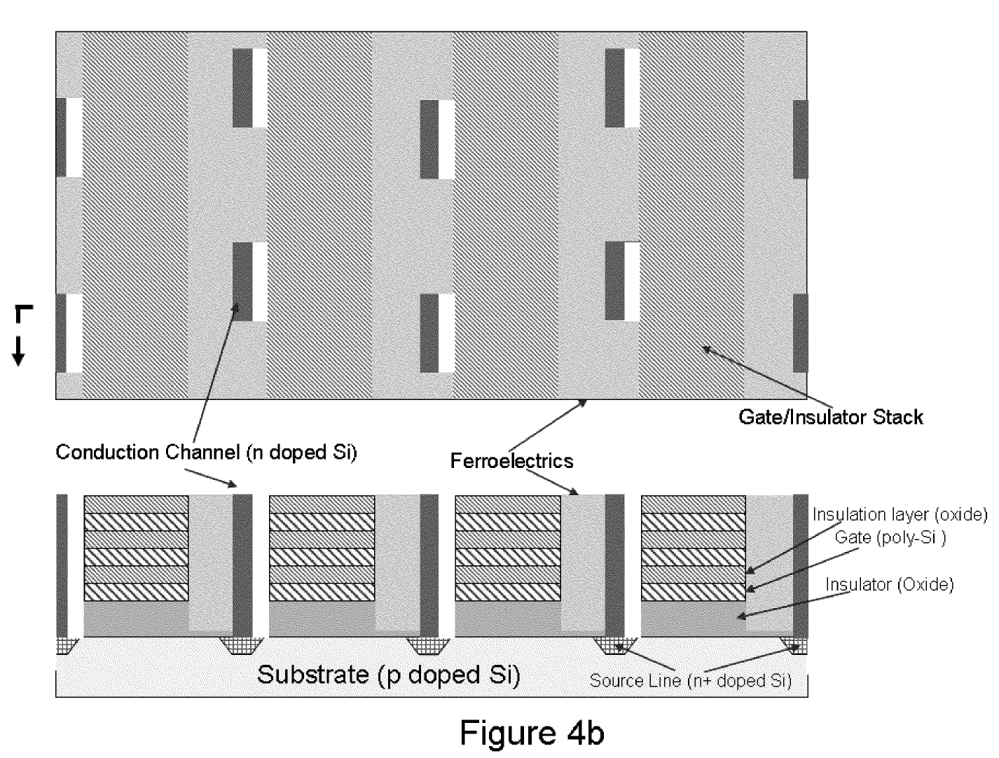

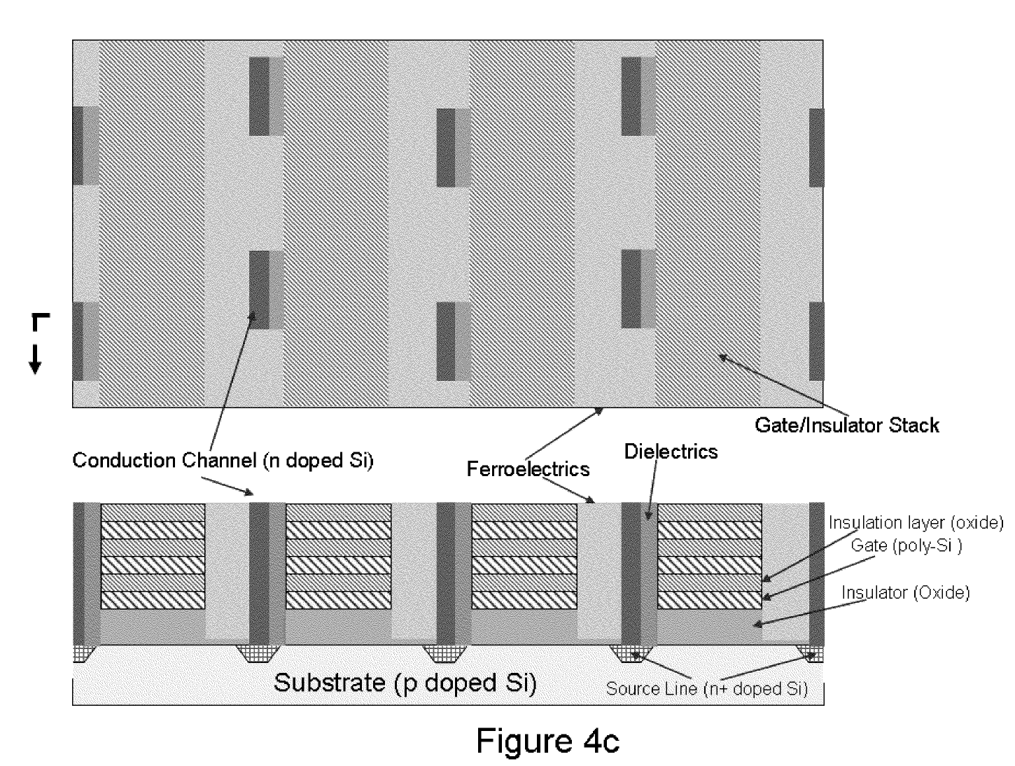

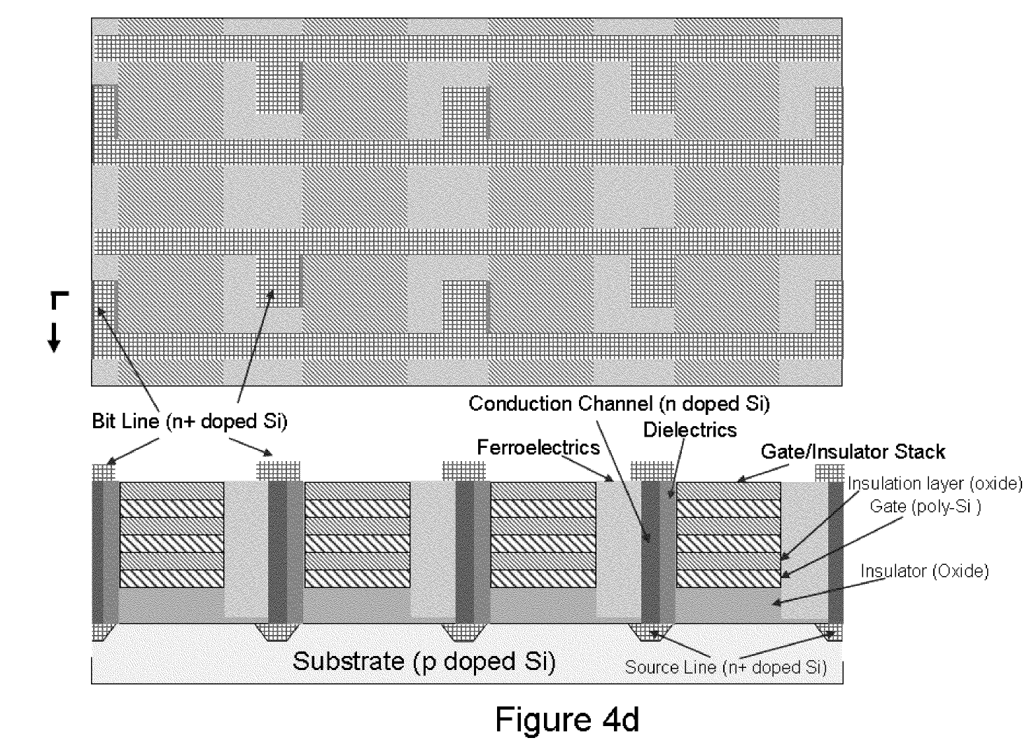

In an alternative embodiment, the present invention comprises another device fabrication method for implementing arrays of the basic vertical memory group of FIG. 1a to form three-dimensional OR-NAND FeRAM devices. This method is different than what is illustrated in FIG. 3, in that a true conventional dielectric material such as SiO₂ or HfO₂ is used as the gate dielectrics for the right-side gate (the RW Control Line). The new fabrication process is modified from that of FIG. 3, starting from the step of FIG. 3d. More specifically, the step of FIG. 3d is replaced by a step depicted in FIG. 4a: (1) the right section of the ferroelectric layer (PZT) is completely etched so that a side wall of the gate/insulator stack is exposed; and (2) the etched holes are then filled with a semiconducting material (e.g. poly-Si, Epi-Si, or Ge in specific cases). After that, part of the semiconductor post is etched (FIG. 4b) to define the conduction channel, followed by the deposition of conventional gate dielectrics (FIG. 4c) such as HfO₂, Al₂O₃, or ZrO₂ by ALD, or SiO₂ by LPCVD. Alternatively, after the etching of the semiconductor post (FIG. 4b), an extra oxidation step (e.g. thermal oxidation) can be taken to convert part of the semiconductor post (on the right side) into an oxide layer, followed by the deposition of conventional gate dielectrics (FIG. 4c) such as HfO₂, Al₂O₃, or ZrO₂ by ALD, or SiO₂ by LPCVD. Finally, the memory device is finished (FIG. 4d) after the preparation of electrodes for Bit Lines (Rows), Source Lines (Rows) and Word Lines/RW Control Lines (stacked gates in columns). The fabrication process of FIG. 4 implements the exact device structure of FIG. 1a.

AND-NOR FeRAMs with FETs Connected in Parallel as a Basic Memory Group and a Read Scheme of AND-NOR Logics for Full Random Access to Individual Memory Cells

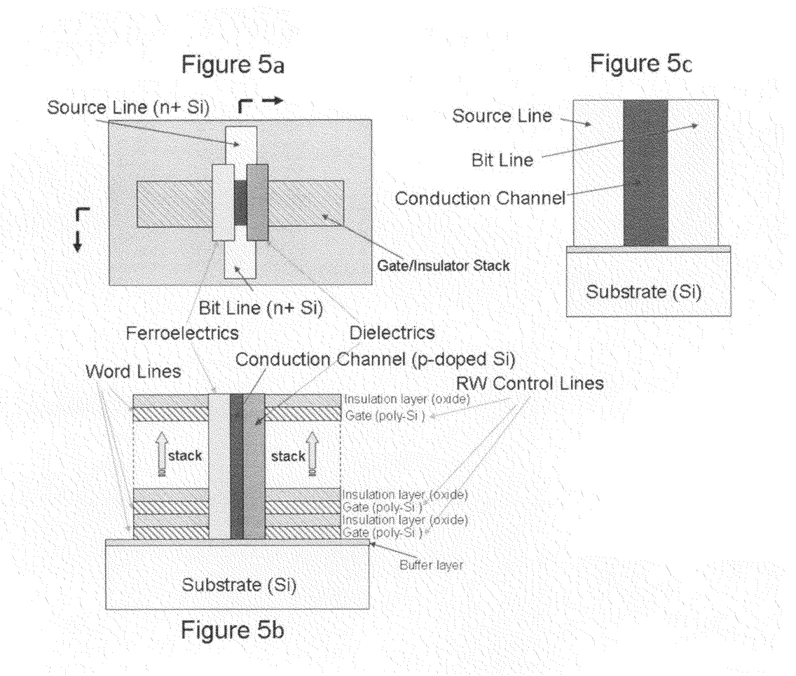

In one embodiment, the present invention comprises a basic AND-NOR memory group consisting of FETs electrically connected in parallel vertically, as illustrated in FIG. 5. Such basic memory groups will be produced and connected in arrays on chip to form non-volatile three-dimensional AND-NOR FeRAM devices. In the present invention, a vertically oriented single piece of semiconductor (e.g., a silicon “fin”, or Ge fin) provides parallel conduction channels for all FETs within the same basic AND-NOR memory group. A double-gate structure is employed for implementing a read/write scheme for the proposed AND-NOR FeRAMs, where one type of gates (serving as the Word Line) employs ferroelectrics layers as gate dielectrics while the other type of gates (serving as the RW Control Line for read/write operations) employs conventional dielectric materials as gate dielectrics. In an alternative configuration, a thin insulator layer (e.g., silicon nitride, HfO₂, Al₂O₃, SiO₂, or ZrO₂ thin film with a preferred thickness from one atomic layer to ˜10 nm) can be sandwiched between the ferroelectric layer and the conduction channel (e.g., Si fin) and/or sandwiched between the ferroelectric layer and the side wall of the gate, which may be useful for increasing the retention time of remnant polarization in the ferroelectric layer. The electrodes for Source Line and Bit Line consist of two degenerately doped semiconductor post (preferably made of the same semiconductor material as the channel), which electrically connect the side ends of the conduction channel (e.g., a silicon fin) so that the electrical current flows horizontally (FIGS. 5a and 5c). The doping configurations of the conduction channel (taking Si fin as an specific example) and the electrodes of Source and Bit Lines (taking degenerately doped Si as an example) are preferred to be as follows (in the case that an inversion layer serves as the electrical conduction path in the FET ON state): (i) the channel is p-doped Si while these two electrodes (Source and Bit Lines) are degenerately n-doped Si; or (ii) the channel is n-doped Si while these two electrodes (Source and Bit Lines) are degenerately p-doped Si. In the case that an accumulation layer serves as the electrical conduction path in the FET ON state, the channel can be a resistive undoped Si while these two electrodes (Source and Bit Lines) are degenerately doped Si with either type of carrier. A basic requirement of workable doping configurations of the conduction channel and the electrodes is to ensure that there should be no conduction path between the source and the drain electrodes when all FETs within the same basic memory group are in the OFF state, which is needed for the AND-NOR read scheme (to be described later).

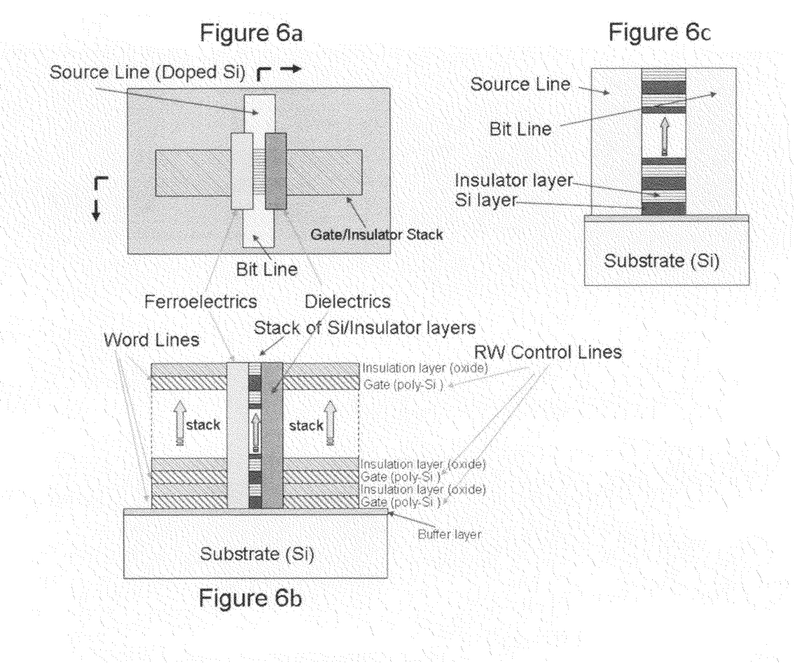

In an alternative embodiment of the invention, the configuration of the basic memory group for vertical AND-NOR FeRAM devices can be modified as illustrated in FIG. 6, where a stack of alternating semiconductor/insulator layers (aligned with the gate stack vertically) is used to form parallel conduction channels for FETs. In this case, the semiconductor layer can be either doped or intrinsic since the insulator layers ensure that all conduction paths are closed when all individual FETs are turned off. Examples of such stacks include alternating Si/SiO₂ layers.

In another embodiment, the present invention comprises a design of a scheme to read/write individual memory cells with full random access in the proposed AND-NOR FeRAM devices with the aforementioned double-gate structure. To read the state of a specific individual memory cell (i.e., a FET), the following scheme is proposed: first, the desired memory group (see FIGS. 5 and 6) containing the target memory cell is selected (i.e., the source electrode of the selected group is electrically connected to a grounded common Source Line and the drain electrode of the group is electrically connected to a common Bit Line), and all Word Lines of the selected memory group are kept floating or grounded (so that the corresponding ferroelectric segments are kept in its existing memory states with remnant polarization undisturbed); next, all RW control lines in the selected memory group except for the one connected to the target memory cell are set at a voltage level V_{off} (so that the corresponding FET are turned off regardless of the remnant polarization of the ferroelectric segment of corresponding left-side gate—Word Line) and the RW Control Line of the target memory cell to read is set at a suitable control voltage level V_{read} (e.g., near the threshold gate voltage of the corresponding FET where the transconductance is maximized) where the state of the corresponding FET is purely determined by the remnant polarization of the ferroelectric segment (i.e., the FET is turned on in one state of the remnant polarization, but turned off in the other state with reversed remnant polarization); finally, the output voltage signal at the Bit Line of the selected group is read to provide information on the state of the target memory cell (if the target cell is in a state with a remnant polarization being able to turn on the associated FET, the Bit Line will be pulled low to the state “0”; otherwise, the Bit Line will stay high at the state “1”), and then the memory group is deselected (i.e. the source and drain electrodes of the group are floated and the Word Lines and RW control lines are reset to appropriate levels, e.g., floating or grounded, to keep the remnant polarization states undisturbed). The presented read scheme is best described as a combined “AND-NOR” logic operation: an AND operation is first performed on a pair of the memory state (remnant polarization of gate ferroelectrics) and the control state at the corresponding dielectric gate (RW Control Line) for every memory cell in the same memory group; and then the outputs of all those AND operations go through a NOR operation to determine the state of the Bit Line.

In an alternative read scheme, instead of reading the output voltage signal at the Bit Line of the selected group in the final reading step (as previously described), one can also monitor the electrical current flow from the Bit Line to the Source Line via a sense amplifier to provide information on the state of the target memory cell. Since a remnant polarization is able to modulate the current flow of the associated FET for the target cell, there should be a larger electrical current flow from the Bit Line to the Source Line in one state; while such an electrical current flow will be smaller in another remnant polarization state. This reading scheme may be more sensitive than the previous reading scheme, if the remnant polarization is not able to turn the associated FET completely on or off even when the control voltage level V_{read} is optimally set near the threshold gate voltage of the corresponding FET where the transconductance is maximized.

Also, writing can be done either one by one on any individual memory cell, or in parallel on any combination of memory cells selected from the same group. To program the state of a specific individual memory cell (FET), the following scheme can be used: (1) the desired memory group containing the target memory cell is selected (i.e., the source electrode of the selected group is electrically connected to a grounded common Source Line and the drain electrode of the group is electrically connected to a grounded common Bit Line), and all Word Lines of the selected memory group are kept floating or grounded (so that the corresponding ferroelectric segments are kept in its existing memory states with remnant polarization undisturbed); (2) the RW control line of the target memory cell is set at a voltage level Vₒₙ so that the corresponding FET is turned on (regardless of the remnant polarization of its ferroelectric segment) and its conduction channel is at the same electrostatic potential (i.e. grounded); (3) the Word Line of the target memory cell is set at a desired writing voltage level V_{write} for a short period of time to apply an electric field (with amplitude greater than the coercive field of the ferroelectrics) across the ferroelectric layer and thus program the remnant polarization state of the ferroelectric segment as desired; (4) finally, the memory group is deselected (i.e. the source and drain electrodes of the group are floated and the Word Lines and RW control lines are reset to appropriate levels, e.g., floating or grounded, to keep the remnant polarization states undisturbed). To program a plurality of selected memory cells in a group in parallel, the only difference lies in the second last step for writing, where the Word Lines of all target memory cells are set at the desired writing voltage level V_{write} simultaneously to program the remnant polarization states. This parallel writing process enables fast program speed, which will be useful for periodically refreshing stored information in FeRAMs if necessary.

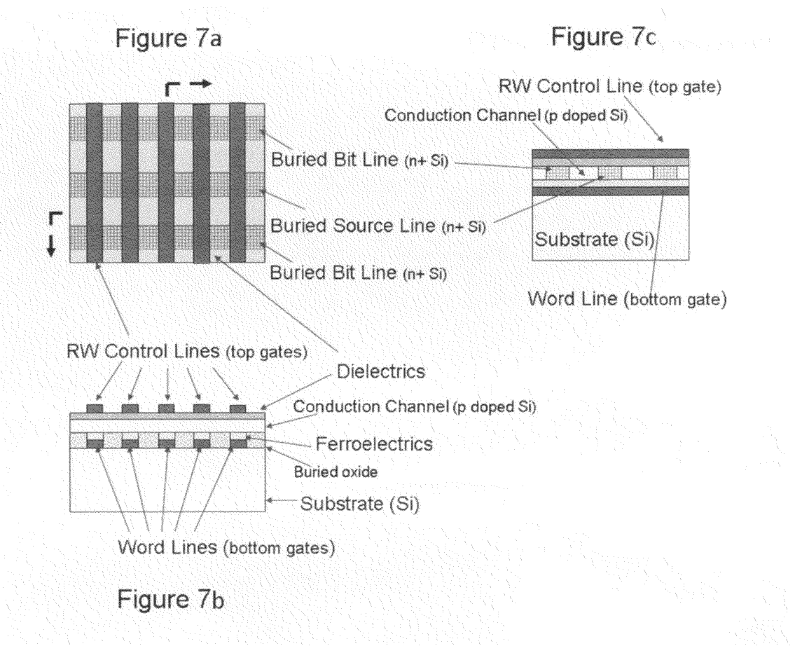

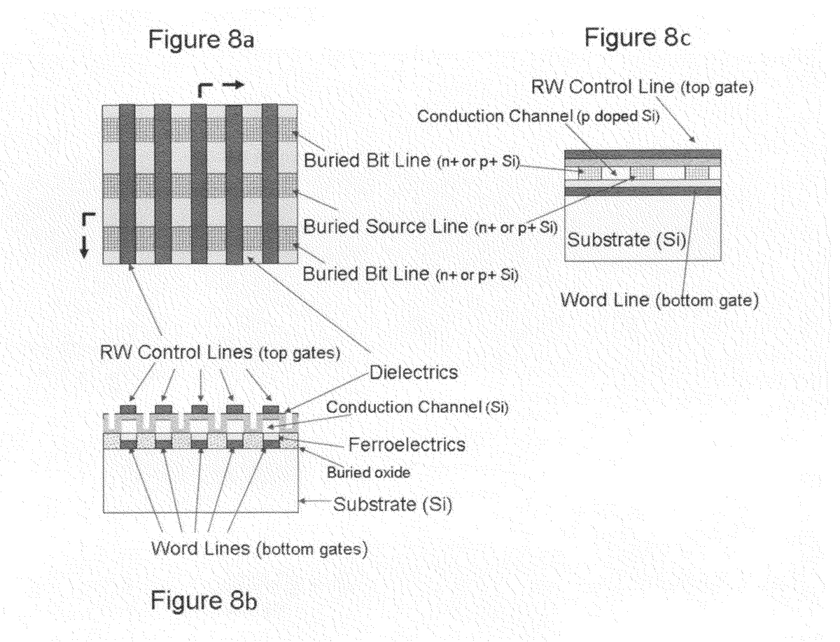

In an alternative embodiment of the invention, the above read/write scheme for AND-NOR FeRAM devices with double-gate structure can also be implemented in a planar geometry with FETs electrically connected in parallel. A example array of basic planar AND-NOR memory groups is shown in FIG. 7, where a set of bottom gates (serving as the Word Line) employ ferroelectrics layers as gate dielectrics while a set of top gates (serving as the RW Control Line for read/write operations) employs conventional dielectric materials as gate dielectrics. Here the Word Lines/RW Control Lines are connected in columns, while the Source Lines and Bit Lines are connected in rows to form planar AND-NOR FeRAM devices. The conduction channel can be made of an epitaxial Si or poly-Si layer. The doping configurations of the conduction channel (epitaxial Si layer) and the electrodes of Source and Bit Lines (degenerately doped regions in the Si layer) are preferred to be as follows (in the case that an inversion layer serves as the electrical conduction path in the FET ON state): (i) the channel is p-doped Si while these two electrodes (Source and Bit Lines) are degenerately n-doped Si regions; or (ii) the channel is n-doped Si while these two electrodes (Source and Bit Lines) are degenerately p-doped Si regions. In the case that an accumulation layer serves as the electrical conduction path in the FET ON state, the channel can be a resistive undoped Si while these two electrodes (Source and Bit Lines) are degenerately doped Si with either type of carrier. Alternatively (FIG. 8), the silicon segments between adjacent parallel conduction channels can be etched away and filled with insulating dielectrics, in which case the Si channel can be in any doping configuration and the electrodes for Source and Bit Lines can be degenerately doped with either type of carrier. Also, alternative configurations of the dielectric layer and the ferroelectric layer for such planar AND-NOR FeRAM devices can be implemented, in a fashion in analogy to those planar OR-NAND FeRAM devices listed in FIG. 2.

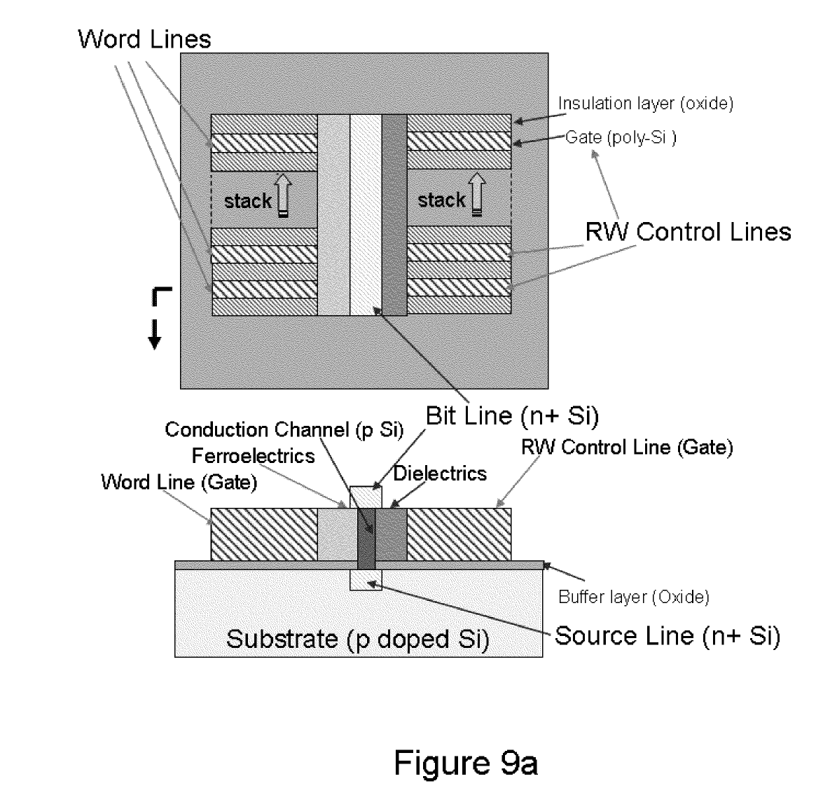

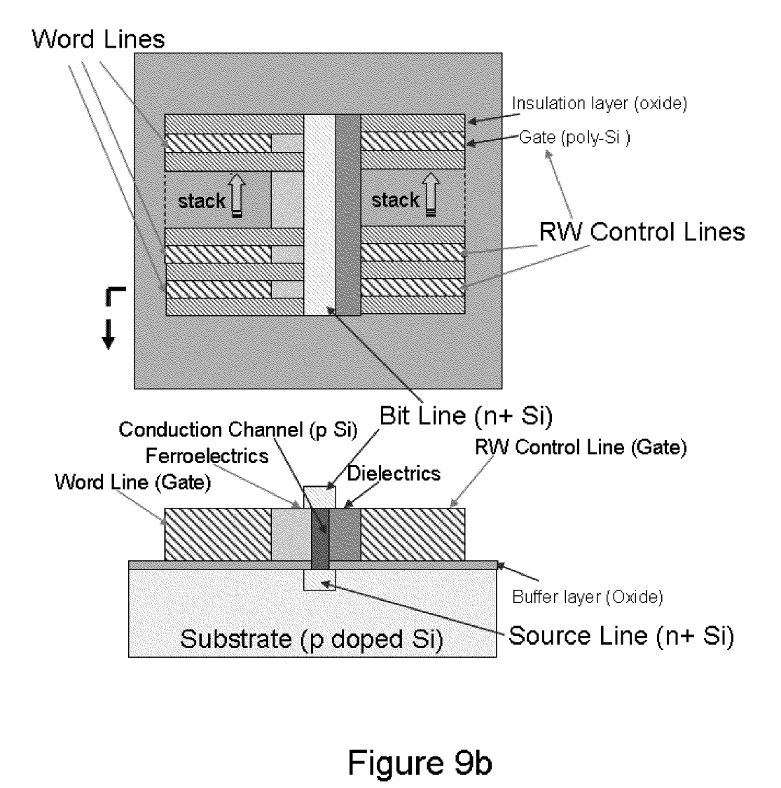

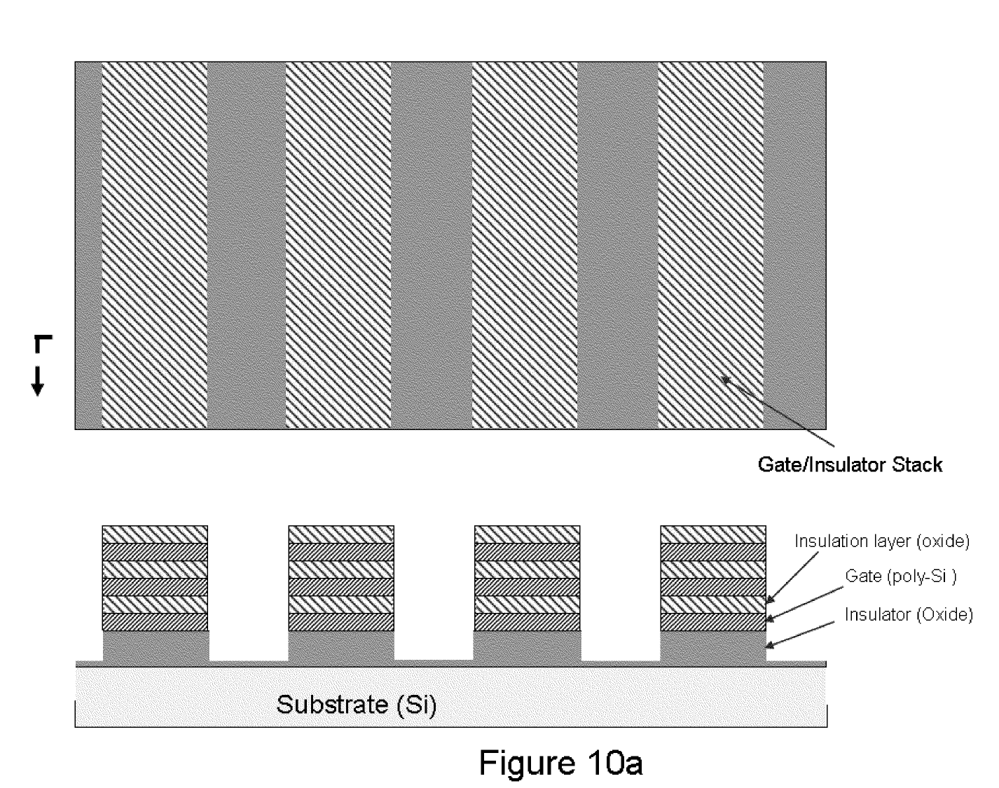

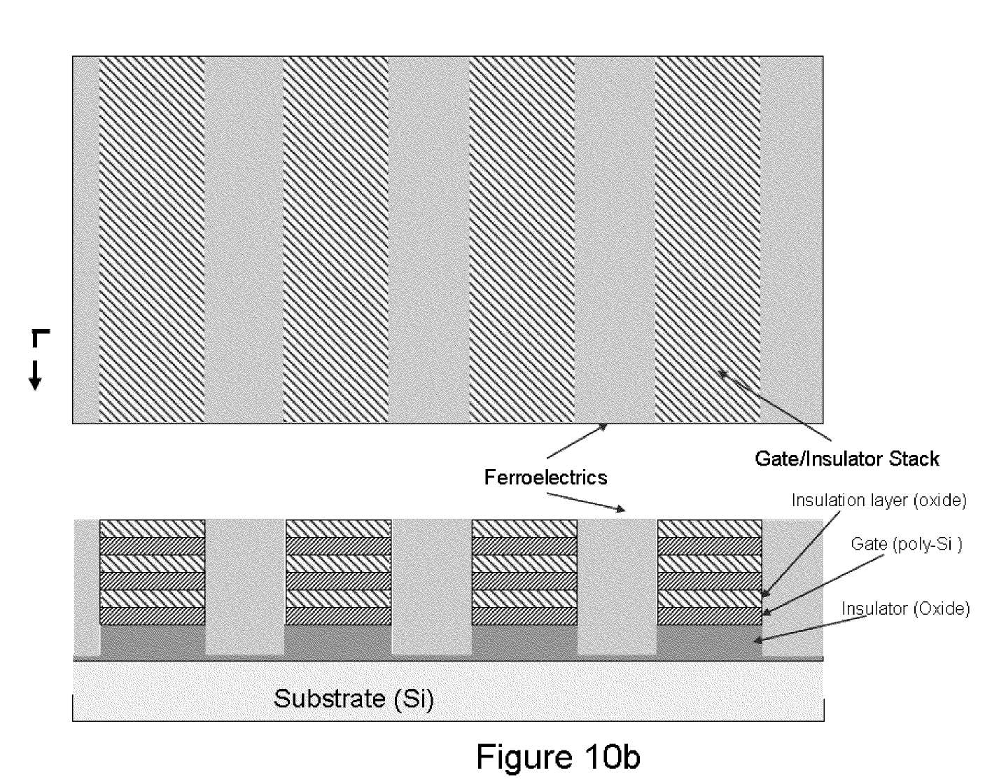

In addition, the relative positions of the ferroelectric gate and the conventional dielectric gate can be adjusted in modified versions of planar AND-NOR FeRAM memory devices, as long as a read/write scheme with full random access to all individual memory cells can be realized with two types of gates. For example, for the planar basic memory groups of FIGS. 7 and 8, the ferroelectric gate can be changed to the top position with the conventional dielectric gate on the bottom. Alternatively, side gates can be configured as shown in the basic planar memory group of FIGS. 9a and 9b. Such basic planar AND-NOR memory groups of FIGS. 7-9 can be produced and connected in arrays on chip (along directions either within the substrate plane or out of the substrate plane via layer-by-layer stacking) to form non-volatile three-dimensional AND-NOR FeRAM devices.

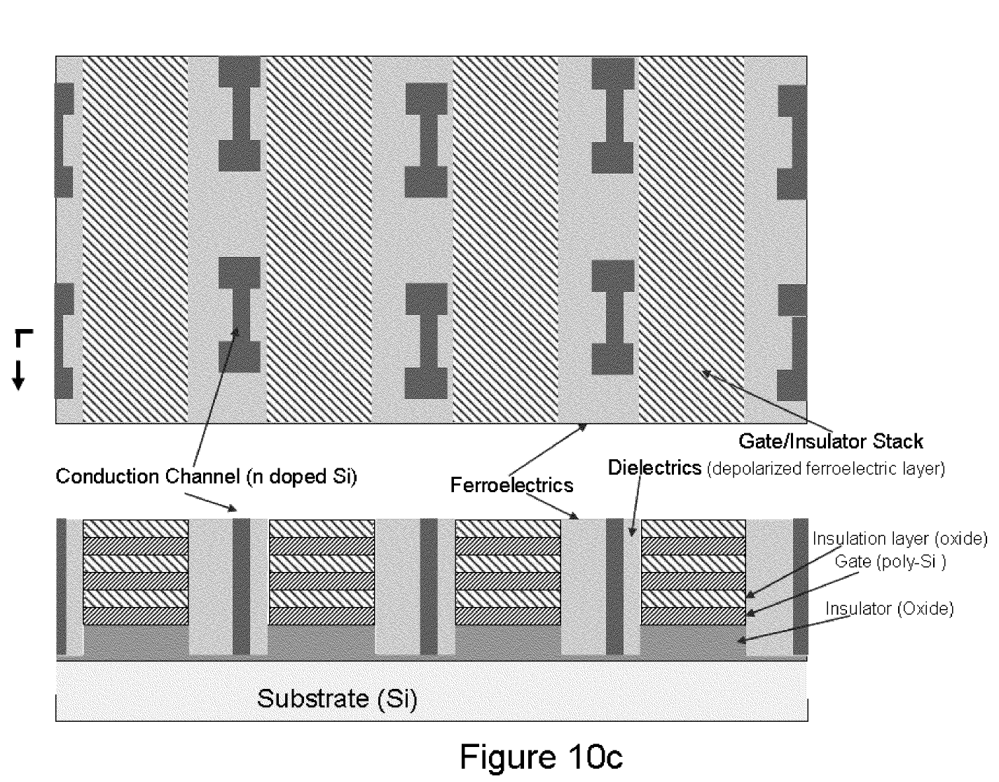

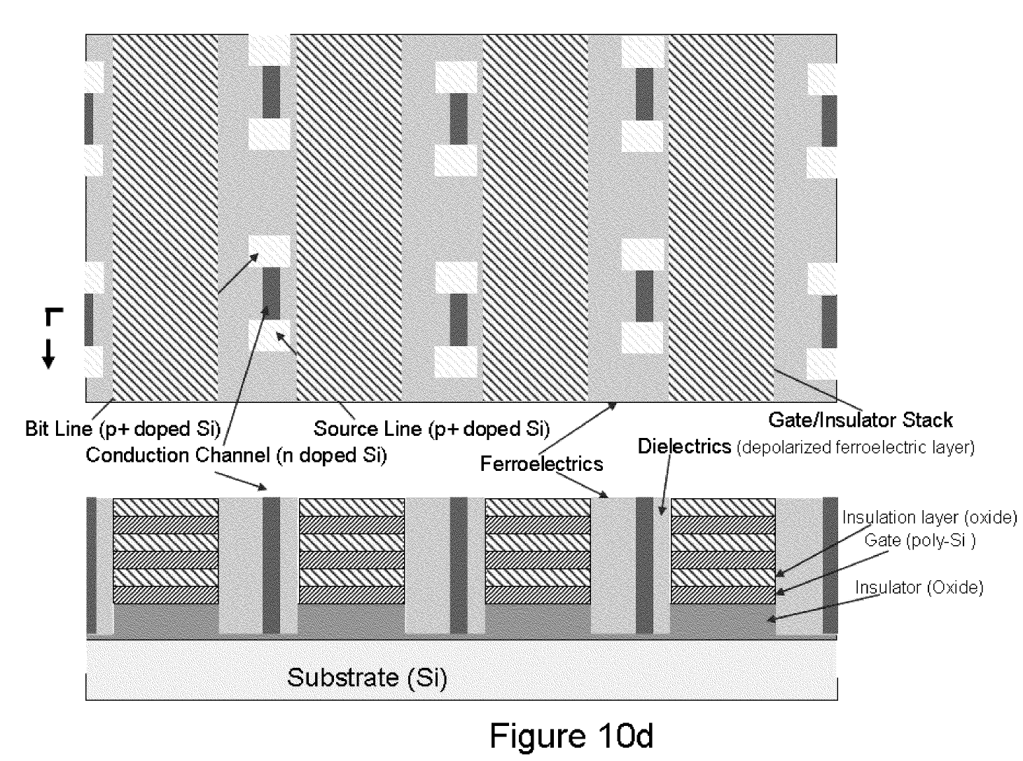

In some embodiments, the present invention comprises device fabrication methods for implementing arrays of the basic vertical memory group of FIG. 5 to form three-dimensional AND-NOR FeRAM devices. One example of detailed device fabrication process is illustrated in FIGS. 10a-10d. First, an insulator layer of SiO₂ (or other insulator) typically in the order of 100 nm thick is deposited on a Si wafer, followed by a blanket deposition of a stack of alternating gate/insulation layers. In one example, the gate layer can be a heavily doped poly-Si prepared by LPCVD, and the insulation layer can be SiO₂ prepared by LPCVD. In an alternative example, the gate layer can be a conducting layer (e.g. TiN or metals) prepared by atomic layer deposition (ALD), and the insulation layer can be HfO₂, Al₂O₃, or ZrO₂ prepared by ALD. The thickness of the gate and insulation layers can be varied depending on the desired storage density and the performance, although typical thickness of the gate layer can be from 10 nm to 500 nm and the insulation layer should be sufficiently thick (e.g., >30 nm in some embodiments) to suppress interference between neighboring memory cells during operations. After that, the gate/insulation multilayer stack is etched into stripes as shown in FIG. 10a, via techniques such as masked ion-milling, or other dry etching and wet etching methods. Next, as shown in FIG. 10b, a ferroelectric layer is grown on the substrate (with the leftover SiO₂ as buffer layer) via thin film techniques such as physical vapor deposition (e.g., thermal evaporation, sputtering, pulsed laser ablation, and etc.), chemical vapor deposition, atomic lay deposition (ALD), Sol-Gel method, chemical solution deposition method, or other chemical reaction methods. Alternatively, one can grow another buffer layer before the deposition of the ferroelectrics to facilitate the growth of high-quality ferroelectric layer on top. The material candidates of the buffer layer include silicon dioxide, MgO, and SrTiO3. The material candidates of ferroelectrics include lead zirconate titanate (PZT), BaTiO₃, Ba₁₋ₓSrₓTiO₃ and BiFeO3; and the thickness of the ferroelectric layer depends on the number of memory cells (FETs) that will be designed for a vertical AND-NOR memory group shown in FIG. 5. After that, arrays of holes are etched all the way through the ferroelectric layer (taking PZT as a specific example material), and then filled by epitaxial silicon or poly-silicon via CVD or LPCVD to form the conduction channel (FIG. 10c). In the case that epitaxial silicon is grown by CVD, the bottom of the holes needs to be etched in the prior step to expose the Si substrate (followed by surface cleaning), and the doping profile of the Si substrate needs to be chosen appropriately to avoid parasitic leakage current between the source and drain at the OFF state. The width of the PZT segment to the right side of the semiconductor channel is designed to be less than a critical dimension, so that the depolarization effect due to the finite size of the corresponding PZT segment is able to cause a loss (or significant degrading) of hysteresis loop in the polarization response, and thus this PZT segment behaves effectively as a conventional dielectrics without appreciable remnant polarization. Subsequently, electrodes for the Source and Bit Lines are prepared via masked ion implantation in selected area to form degenerately doped regions (FIG. 10d). In one preferred configuration, the semiconductor channel is n-doped (p-doped) Si while the electrodes for the Source and Bit Lines are degenerately p-doped (n-doped), so that an inversion layer serves as the electrical conduction path in the FET ON state. In an alternative configuration, the channel can be a resistive undoped Si while the electrodes for Source and Bit Lines are degenerately doped with either type of carrier, so that an accumulation layer serves as the electrical conduction path in the FET ON state. In the end, the memory device is finalized by connecting electrodes for Bit (Source) Lines in every other column to form rows, and every column shares the same Word Line/RW Control Line (stacked gates in columns).

In an alternative embodiment, the present invention comprises another device fabrication method for implementing arrays of the basic vertical memory group of FIG. 5 to form three-dimensional AND-NOR FeRAM devices. In this method, a true conventional dielectric material such as SiO₂ or HfO₂ is used as the gate dielectrics for the right-side gate (the RW Control Line). The fabrication process is modified from that of FIG. 10, by replacing the step of FIG. 10c with steps similar to what are described for FIGS. 4a-4c: (1) the right section of the ferroelectric layer (PZT) is completely etched so that a side wall of the gate/insulator stack is exposed; and (2) the etched holes are then filled with a semiconducting material (e.g. poly-Si, Epi-Si, or Ge in specific cases). Next, part of the semiconductor fin is etched to define the conduction channel, followed by the deposition of conventional gate dielectrics such as HfO₂, Al₂O₃, or ZrO₂ by ALD, or SiO₂ by LPCVD. Alternatively, after the etching of the semiconductor fin, an extra oxidation step (e.g. thermal oxidation) can be taken to convert part of the semiconductor fin (on the right side) into an oxide layer, followed by the deposition of conventional gate dielectrics such as HfO₂, Al₂O₃, or ZrO₂ by ALD, or SiO₂ by LPCVD. After that, electrodes for the Source and Bit Lines are prepared via masked ion implantation in selected areas to form degenerately doped regions, and then the memory device is finalized after connecting Bit Lines (in rows), Source Lines (in rows) and Word Lines/RW Control Lines (stacked gates in columns).

In another alternative embodiment, to form three-dimensional AND-NOR FeRAM devices, arrays of the basic memory group of FIG. 5, 6 or 9 can also be implemented on bulk silicon wafers, where the conduction channel (silicon fin) is implemented via etching into a Si wafer (e.g., similar to the design of FIG. 2g).

Three-Dimensional Transistor-Capacitor Type NAND FeRAMs with Stacked Ferroelectric Capacitors and FETs Electrically Connected in Series as a Basic Memory Group

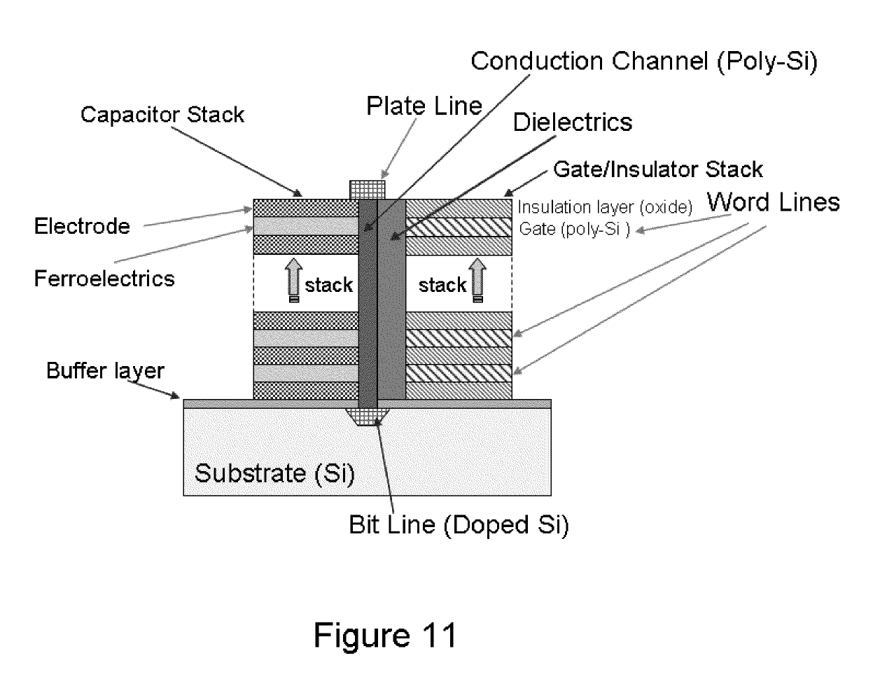

In one embodiment, the present invention comprises a basic NAND memory group consisting of pairs of FET and ferroelectric-capacitor which are electrically connected in series vertically (or along a direction out of the plane of the substrate), as illustrated in FIG. 11. Such basic NAND memory groups will be produced and connected in arrays on chip to form non-volatile three-dimensional transistor-capacitor type NAND FeRAMs. In the present invention (Figure. 11), a vertical poly-silicon post (or post of other semiconductors including Ge and Si) serves as the conduction path for FETs vertically connected in series; the left-side of the poly-Si post is connected to a stack of capacitors with ferroelectrics (e.g. lead zirconate titanate PZT, BaTiO₃, Ba₁₋ₓSrₓTiO₃ or BiFeO₃) as the charge-storage medium and part of the poly-Si post is electrically connected to the electrodes (e.g. metal layers such as Pt, or conducting layers of Nb doped SrTiO₃, or SrRuO₃) of the stacked capacitors; the right-side gates employs conventional dielectrics (e.g. HfO₂, SiO₂, Al₂O₃, or ZrO₂) as gate dielectrics and serve as the Word Lines. Each stacked ferroelectric capacitor is paired with a FET defined by a stacked gate: more specifically, the source and drain sections of the paired FET are electrically connected to these two electrodes of the paired ferroelectric capacitor, respectively. To function as NAND FeRAM devices, the top of the vertical conduction channel (poly-Si post) is connected to a Plate Line and its bottom is connected to a Bit Line via a degenerately doped silicon region on the substrate. In the case that an accumulation layer is used for electrical conduction in the FET ON state, one preferred material configuration is: a p-doped or n-doped poly-Si (or Si) post as the conduction channel and degenerately doped Si regions (with the same doping type as the conduction channel) as the contact nodes for Plate Line and Bit Line. The number of individual memory cell (i.e., a transistor-capacitor pair) along a single vertical conduction path (poly-silicon post) is determined by the number of layers of the alternating insulation/gate (e.g. oxide/poly-silicon) stack, and therefore determines the storage density of the three-dimensional transistor-capacitor type NAND FeRAMs. In addition, a plurality of such basic NAND memory groups shown in FIG. 11 can be connected in series to form a larger NAND memory group. On the chip level, these NAND memory groups can be connected via additional FETs to form Bit/Plate Line arrays for the purpose of addressing every NAND memory group.

In an alternative embodiment, for the basic NAND memory group of FIG. 11, the top most FET in the stack can function as a Plate Line block selector to disconnect or connect the basic group from the Plate Line, and the bottom most FET in the stack can function as a Bit Line block selector to disconnect or connect the basic group from the Bit Line during read/write operations.

In another embodiment, the scheme to read/write individual memory cells with full random access within the basic NAND memory group of FIG. 11 can be described as NAND-type logics, similar to the chain-type planar one-transistor-one-capacitor FeRAMs. To read the state of a specific individual memory cell (i.e., the remnant polarization state of the corresponding ferroelectric capacitor), the following scheme is proposed: (1) the desired memory group (see FIG. 11) containing the target memory cell is selected (i.e., the Bit Line and the Plate Line of the selected group are electrically connected); (2) all other Word Lines of the selected memory group are kept at Vₒₙ (so that every corresponding FET is turned on and the two electrodes of the corresponding ferroelectric capacitor are at equal potential, thus keeping the existing memory states with remnant polarization undisturbed) but the Word Line of the target cell is set at V_{off} (so that the corresponding FET is turned off and the corresponding ferroelectric capacitor is electrically connected to the Bit Line and the Plate Line at two ends, respectively); (3) the Plate Line potential is raised to a high level and after a short period of time the Bit Line is connected to a sense amplifier (and compared with a reference data) to read out the polarization state of the ferroelectric capacitor; (4) the Plate Line potential is lowered to the low level for a short period of time so that either polarization state can be refreshed in this or the previous step; (5) the memory group is then deselected (i.e. the Bit Line and the Plate Line of the selected group are electrically disconnected and the Word Lines are reset to an appropriate level, e.g., Vₒₙ). To write the state of a specific individual memory cell, the operation is similar to the data read operation described above except for step 3: here the Plate Line potential is raised to the high level and after a short period of time the to-be-written data is supplied to the Bit Line from the outside (if the data is low level, it will be written at step 3 into the ferroelectric capacitor; otherwise, it will be written at step 4 when the Plate Line potential is lowered).

In an alternative embodiment of the present invention, two basic NAND memory groups of FIG. 11 can be configured as a two-transistor-two-capacitor NAND group (with complementary data stored in a pair of cells) by sharing the same Word Lines and the same Plate Line while maintaining their own Bit Lines as a reference pair.

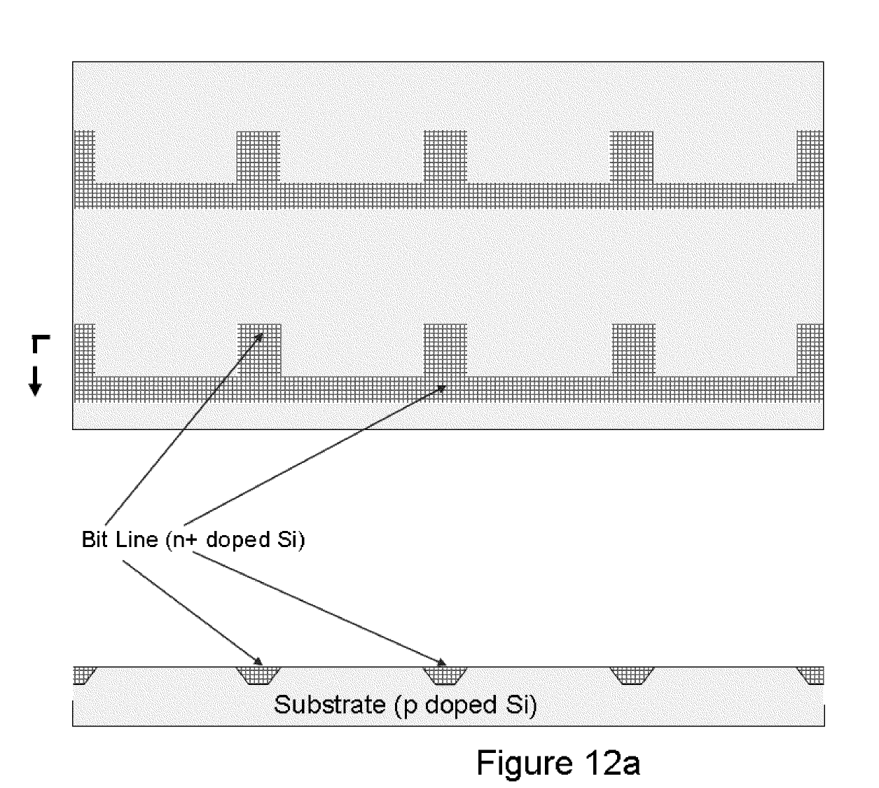

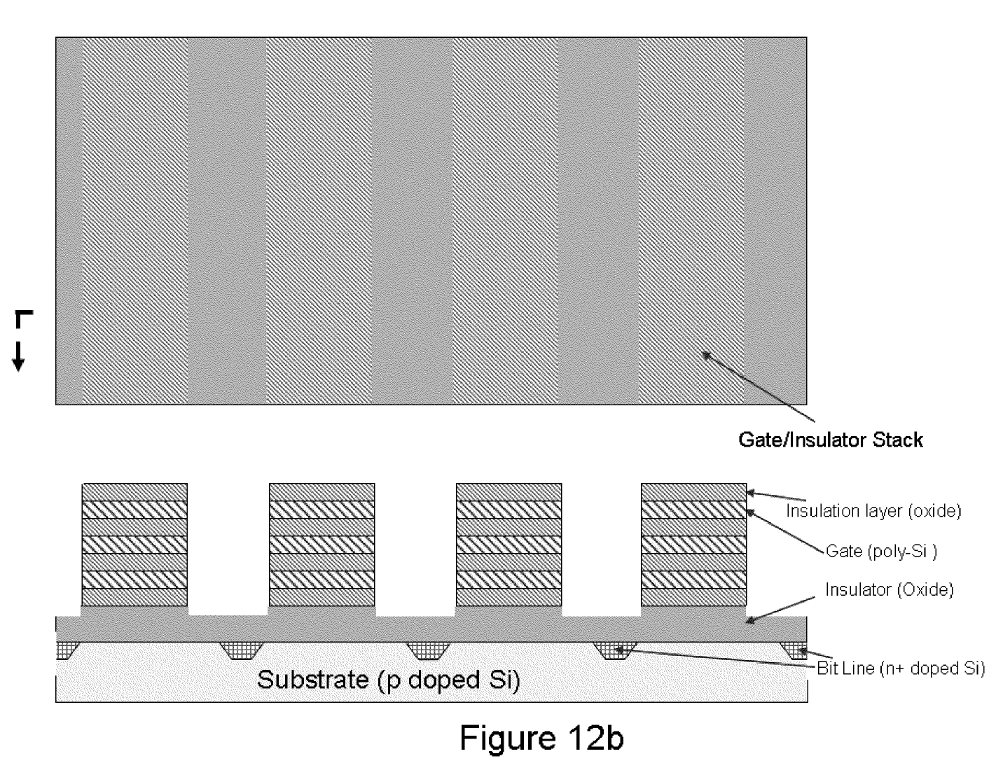

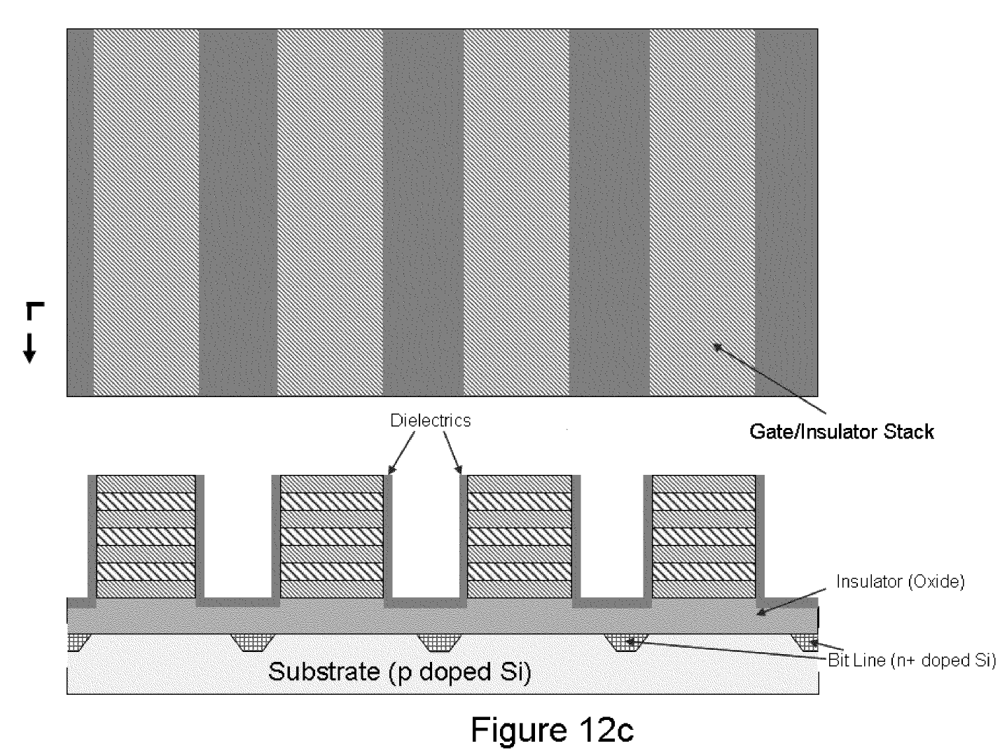

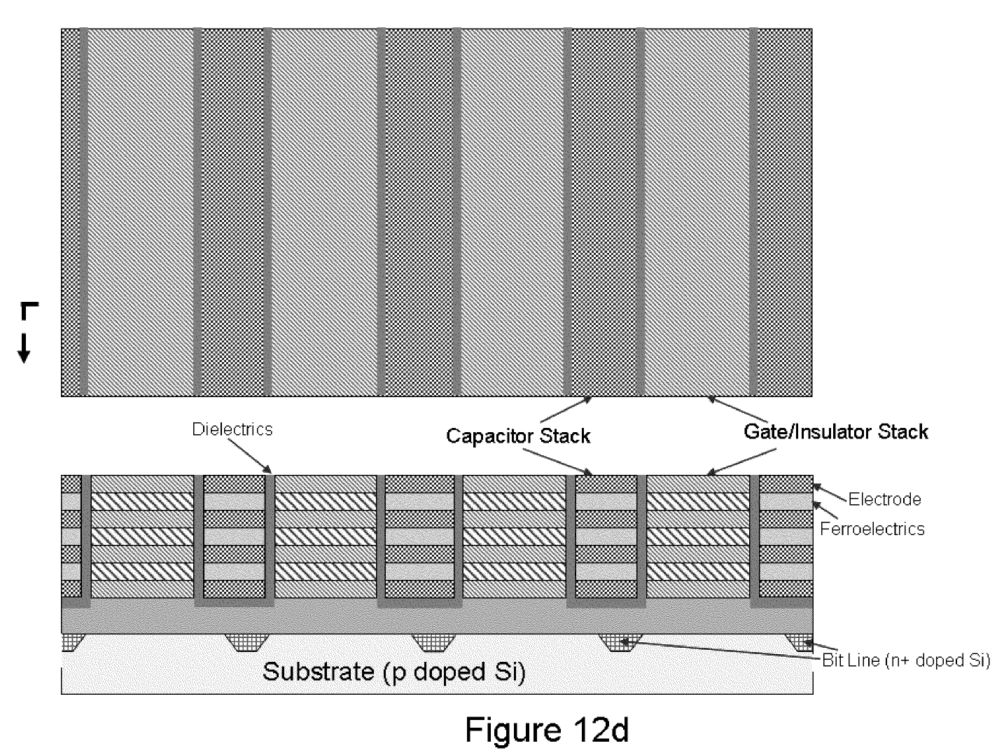

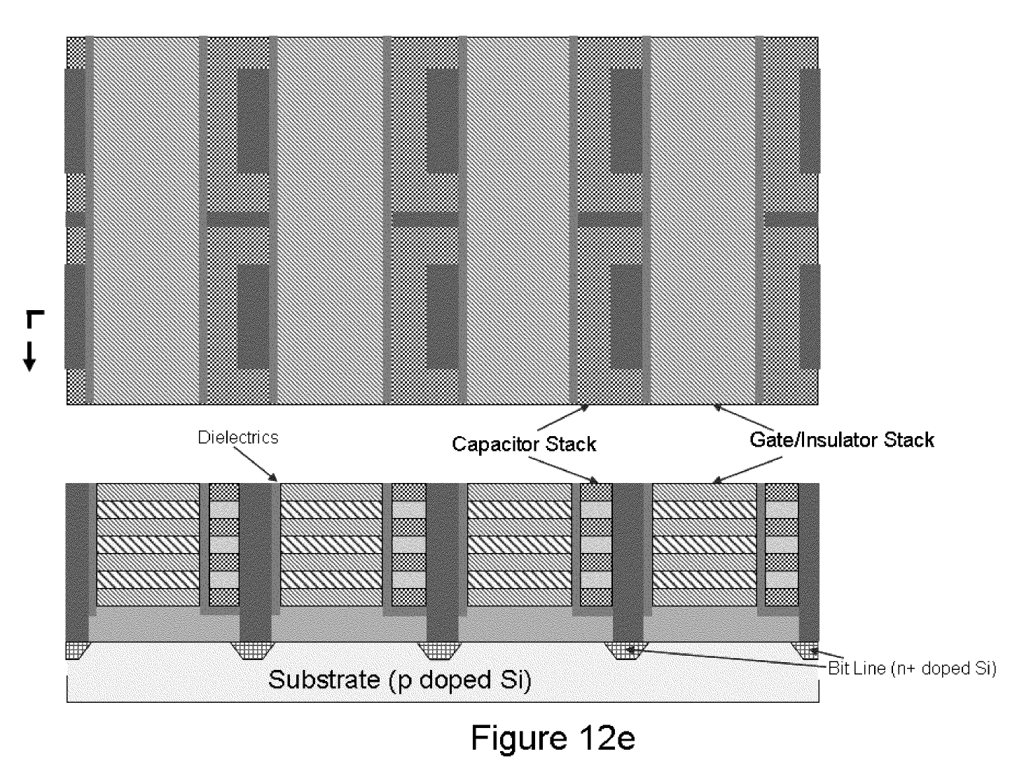

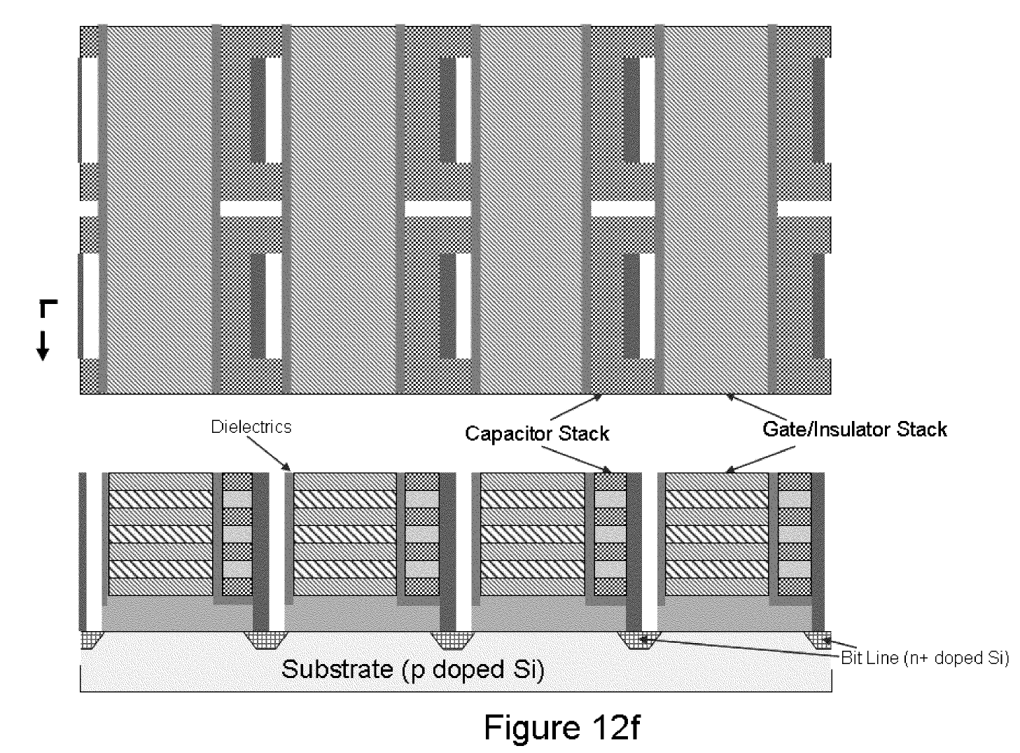

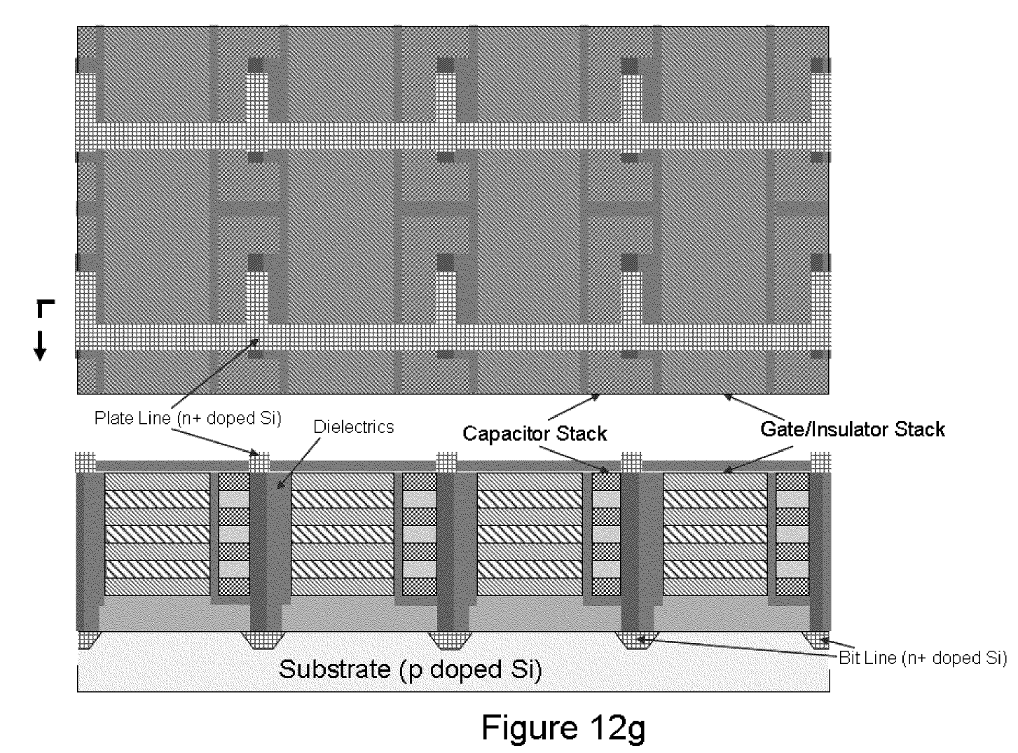

In some embodiments, the present invention comprises device fabrication methods for implementing arrays of the basic NAND memory group of FIG. 11 to form three-dimensional transistor-capacitor type NAND FeRAM devices. One example of detailed device fabrication process is illustrated in FIG. 12. First, arrays of degenerately doped pads are produced and connected on a silicon substrate to form rows of Bit Lines (FIG. 12a), e.g., via ion implantation with a masked pattern. Next, an insulator layer of SiO₂ (or other insulator) typically in the order of 100 nm thick is deposited on the Si wafer, followed by a blanket deposition of a stack of alternating gate/insulation layers. In one example, the gate layer can be a heavily doped poly-Si prepared by LPCVD, and the insulation layer can be SiO₂ prepared by LPCVD. In an alternative example, the gate layer can be a conducting layer (e.g. TiN or metals) prepared by atomic layer deposition (ALD), and the insulation layer can be HfO₂, Al₂O₃, or ZrO₂ prepared by ALD. The number and the thickness of the gate and insulation layers can be varied depending on the desired storage density and the performance, although typical thickness of the gate layer can be from 10 nm to 500 nm and the insulation layer should be sufficiently thick (e.g., >30 nm in some embodiments) to suppress interference between neighboring memory cells during operations. After that, the gate/insulation multilayer stack is etched into stripes as shown in FIG. 12b, via techniques such as masked ion-milling, or other dry etching and wet etching methods. Subsequently, as shown in FIG. 12c, a dielectrics layer (such as HfO₂, Al₂O₃, ZrO₂ or SiO₂) is prepared by ALD or LPCVD to coat the side walls of the gate/insulation stack. Next, capacitor stacks are prepared by deposition of alternating ferroelectrics/electrode layers, with the thickness matching corresponding gate/insulation layers (FIG. 12d). The ferroelectrics layers (e.g., PZT, BaTiO₃, Ba₁₋ₓSrₓTiO₃ or BiFeO₃) can be prepared by thin film techniques such as physical vapor deposition (e.g., thermal evaporation, sputtering, pulsed laser ablation, and etc.), chemical vapor deposition, atomic lay deposition (ALD), Sol-Gel method, chemical solution deposition method, or other chemical reaction methods. Alternatively, a thin buffer layer (e.g., SrTiO₃, Nb doped SrTiO₃, or MgO) can be used before the deposition of the ferroelectrics to facilitate the growth of high-quality ferroelectric layers. The electrode layer can be a metal layer (e.g. Pt), or other conducting layers (e.g., Nb doped SrTiO₃, or SrRuO₃). After that, patterned holes are etched all the way through the capacitor stacks and the insulator layer to expose the Si substrate, followed by the deposition of a semiconductor material such as poly-Si by LPCVD (or epi-Si by CVD) to fill the etched holes (FIG. 12e). After that, part of the semiconductor is etched (FIG. 120 to define the conduction channel with a preferred width from 1 nm to 100 nm. Finally, the gate dielectrics layer (such as HfO₂, Al₂O₃, ZrO₂ or SiO₂) is prepared by ALD or LPCVD to coat the exposed side wall of the conduction channel (alternatively, before this step, the semiconductor conduction channel can also be partially oxidized via thermal oxidation), followed by the preparation of the contacts (e.g., degenerately doped Si) for the Plat Line (FIG. 12g). In this device configuration, the Word Lines (stacked gates) form columns while the Plate Lines and Bit Lines form rows to connect arrays of the basic NAND memory groups.

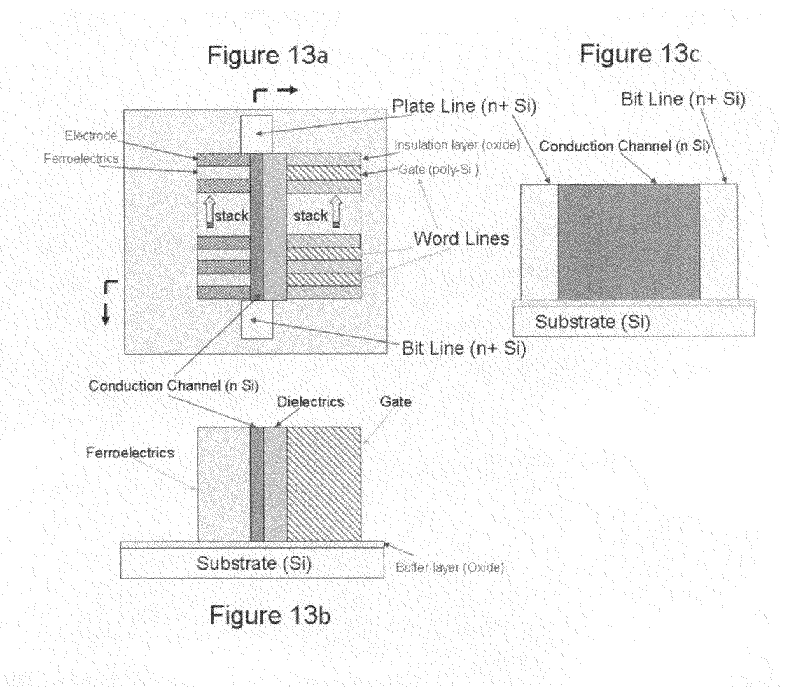

In some embodiments, the present invention comprises a basic NAND memory group consisting of pairs of FET and ferroelectric-capacitor which are electrically connected in series along a direction parallel to the plane of the substrate. Three example architectures of such basic NAND memory groups are shown in FIGS. 13-15, respectively. Such basic NAND memory groups will be produced and connected in arrays on chip (along directions either within the substrate plane or out of the substrate plane) to form non-volatile three-dimensional transistor-capacitor type NAND FeRAMs.

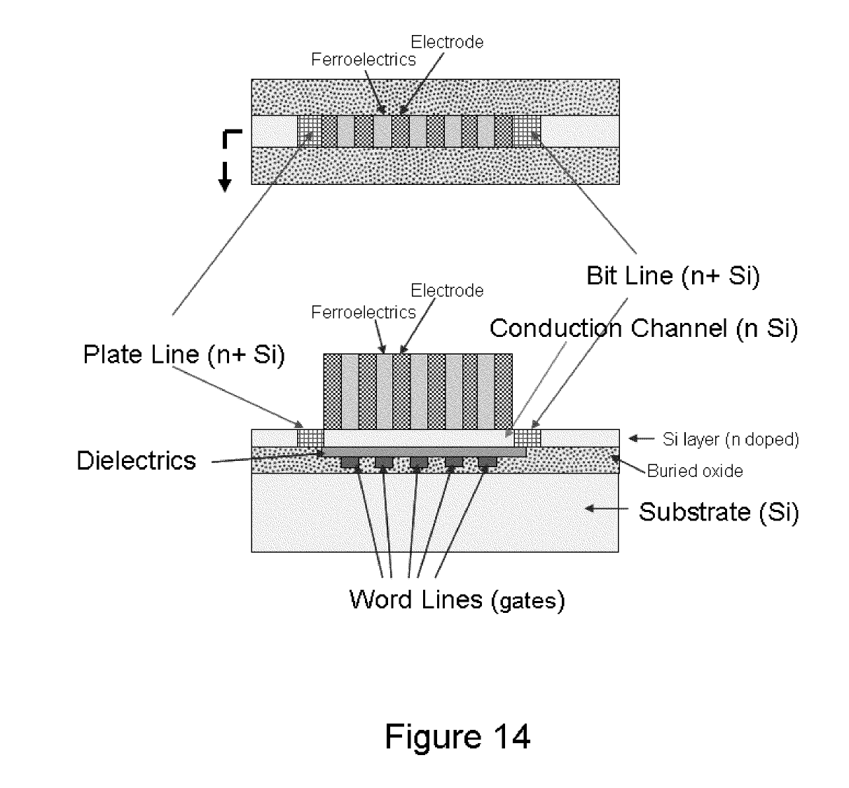

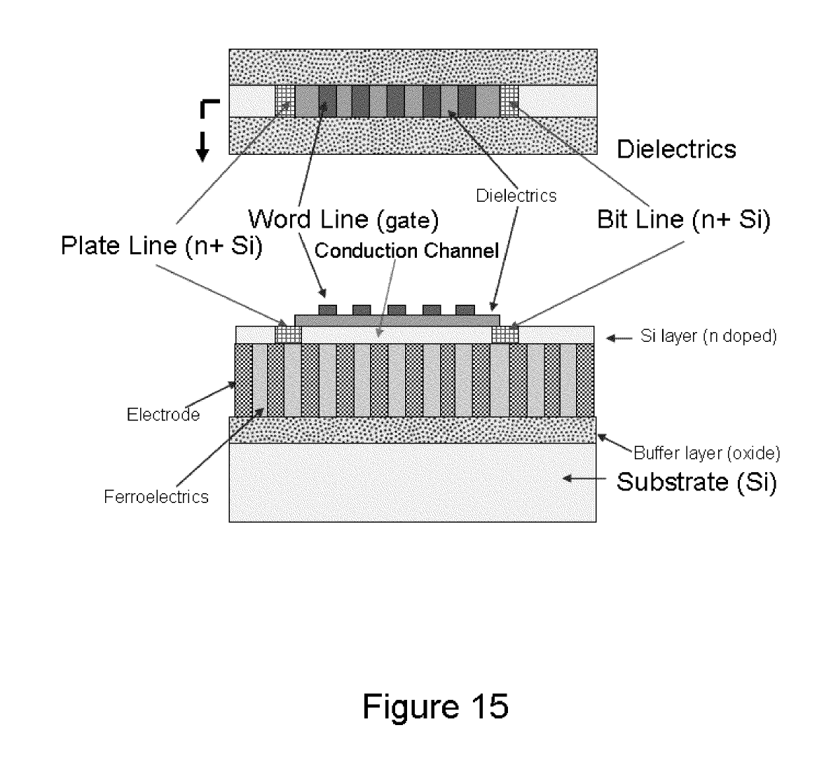

For the basic NAND memory group of FIG. 13, the capacitor stack is in contact with one side of the conduction channel (e.g., a Si fin), and the gate stack is on the other side of the conduction channel (i.e., side gates are used for FETs). Alternatively, the basic NAND memory group of FIG. 13 can also be fabricated on bulk silicon wafers, where the conduction channel (Si fin) is implemented via etching into a Si wafer (e.g., similar to the design of FIG. 2g). For the basic NAND memory group of FIG. 14, bottom gates are used for FETs and the capacitor stack is on top of the conduction channel; while for the basic NAND memory group of FIG. 15, top gates are used for FETs and the capacitor stack is located below the conduction channel. Materials configurations for the basic NAND memory groups of FIGS. 13-15 can be similar to what were aforementioned for the basic NAND memory group of FIG. 11. However, since the conduction channel (between the source and drain) is oriented along a direction parallel to the substrate plane, there are more options for the doping profile of the conduction channel, similar to what was described previously for the devices of FIG. 2. Specifically, in the case that an accumulation layer is used for electrical conduction in the FET ON state, the preferred material configuration for the conduction channel include: (1) a uniformly p-doped or n-doped Si layer (or Si fin) with only two ends of the channel (i.e., contact nodes for the Plate Line and Bit Line) degenerately doped with the same type of carrier as the channel; (2) a p-doped or n-doped Si layer (or Si fin) with the source/drain segments for all individual FETs degenerately doped with the same type of carrier as the channel. In the case that an inversion layer is used for electrical conduction in the FET ON state, the preferred material configuration for the conduction channel include: (1) p-doped Si layer (or Si fin) with the source/drain segments for all individual FETs degenerately n-doped; (2) n-doped Si layer (or Si fin) with the source/drain segments for all individual FETs degenerately p-doped; and (3) a uniformly p-doped (n-doped) Si layer (or Si fin) with only two ends of the channel (i.e., contact nodes for the Plate Line and Bit Line) degenerately n-doped (p-doped). Note that the third configuration mentioned above is useful only when the separation between adjacent gates of the FETs connected in series is less than a critical length (e.g., ˜10 nm or less) so that stray electric fields of neighboring gates are able to tune the source/drain segments connecting adjacent FETs into inversion layers.

1. A non-volatile basic ferroelectric memory group (termed as “OR-NAND basic ferroelectric memory group”) comprising:
(i) a plurality of individual memory cells (i.e., field effect transistors) which are stacked along a direction out of the plane of the substrate and electrically connected in series;
(ii) a piece of silicon (denoted as a silicon “post”) which provides serially connected conduction channels for all field-effect-transistors within the same basic memory group;
(iii) the first type of gates using a ferroelectric layer as the gate dielectrics which functions as the storage medium for individual memory cells;
and
(iv) the second type of gates using a conventional dielectric layer as the gate dielectrics which facilitates the implementation of a read/write scheme with full random access to individual memory cells.

2. The basic ferroelectric memory group of claim 1, wherein a plurality of individual memory cells (i.e., field effect transistors) are stacked along a direction parallel to the plane of the substrate and electrically connected in series.

3. The basic ferroelectric memory group of claim 1, wherein a plurality of individual memory cells (i.e., field effect transistors) are stacked along any directions and electrically connected in series.

4. The basic ferroelectric memory group of claims 1-3, wherein the material of the conduction channel (i.e., the silicon post) is replaced by another doped or undoped semiconductor such as germanium, or an alloy of silicon and germanium.

5. The basic ferroelectric memory group of claims 1-4, wherein a thin insulator layer (including but not limited to silicon nitride, HfO₂, Al₂O₃, SiO₂, or ZrO₂ thin film) is sandwiched between the ferroelectric layer and the conduction channel (i.e., the semiconductor post), and/or sandwiched between the ferroelectric layer and the corresponding gate electrode for each field effect transistor.

6. The basic ferroelectric memory group of claims 1-5, wherein the second type of gates use a depolarized ferroelectric layer (i.e., with no or negligible hysteresis in polarization response) as the gate dielectrics which facilitates the implementation of a read/write scheme with full random access to individual memory cells.

7. A non-volatile basic ferroelectric memory group (termed as “AND-NOR basic ferroelectric memory group”) comprising:
(i) a plurality of individual memory cells (i.e., field effect transistors) which are stacked along a direction out of the plane of the substrate and electrically connected in parallel (i.e., sharing the source and drain electrodes);
(ii) a piece of silicon (denoted as a silicon “fin”) which provides parallel conduction channels for all field-effect-transistors within the same basic memory group;
(iii) the first type of gates using a ferroelectric layer as the gate dielectrics which functions as the storage medium for individual memory cells;
and
(iv) the second type of gates using a conventional dielectric layer as the gate dielectrics which facilitates the implementation of a read/write scheme with full random access to individual memory cells.

8. The basic ferroelectric memory group of claim 7, wherein a plurality of individual memory cells (i.e., field effect transistors) are stacked along a direction parallel to the plane of the substrate and electrically connected in parallel (i.e., sharing the source and drain electrodes).

9. The basic ferroelectric memory group of claim 7, wherein a plurality of individual memory cells (i.e., field effect transistors) are stacked along any directions and electrically connected in parallel (i.e., sharing the source and drain electrodes).

10. The basic ferroelectric memory group of claims 7-9, wherein the material of the conduction channel (i.e., the silicon fin) is replaced by another doped or undoped semiconductor such as germanium, or an alloy of silicon and germanium.

11. The basic ferroelectric memory group of claims 7-10, wherein the semiconductor fin (conduction channel) is replaced by a stack of alternating semiconductor/insulator layers (or segments) to provide parallel conduction channels for all field-effect-transistors within the same basic memory group.

12. The basic ferroelectric memory group of claims 7-11, wherein a thin insulator layer (including but not limited to silicon nitride, HfO₂, Al₂O₃, SiO₂, or ZrO₂ thin film) is sandwiched between the ferroelectric layer and the conduction channel, and/or sandwiched between the ferroelectric layer and the corresponding gate electrode for each field effect transistor.

13. The basic ferroelectric memory group of claims 7-12, wherein the second type of gates use a depolarized ferroelectric layer (i.e., with no or negligible hysteresis in polarization response) as the gate dielectrics which facilitates the implementation of a read/write scheme with full random access to individual memory cells.

14. The double-gate structure of the basic ferroelectric memory group of claims 1-13 for implementing read/write schemes with full random access to individual memory cells within the basic memory group, comprising: (i) the first type of gates employing ferroelectric materials as the gate dielectrics, and (ii) the second type of gates employing conventional dielectric materials as the gate dielectrics.

15. The double-gate structure of claim 14, wherein a combined OR-NAND logic is employed to read the stored information of each individual memory cell, and writing of storage information can be done either one by one on any individual memory cell, or in parallel on any combination of memory cells from the same ferroelectric memory group.

16. The double-gate structure of claim 14, wherein a combined AND-NOR logic is employed to read the stored information of every individual memory cell, and writing of storage information can be done either one by one on any individual memory cell, or in parallel on any combination of memory cells from the same ferroelectric memory group.

17. A non-volatile basic ferroelectric memory group (termed as “transistor-capacitor type NAND basic ferroelectric memory group”) comprising:
(i) a plurality of individual memory cells (i.e., pairs of field-effect-transistor and ferroelectric-capacitor with one electrode of the capacitor connected to the source of the transistor and the other electrode connected to the drain of the transistor) which are stacked along a direction out of the plane of the substrate and electrically connected in series;
(ii) a piece of semiconductor such as Si, Ge or Si/Ge alloy (denoted as a semiconductor “post”) which provides serially connected conduction channels for all field-effect-transistors within the same basic memory group;
(iii) a Plate Line connected to one end of the semiconductor post, and a Bit Line connected to the other end of the semiconductor post;
and
(iv) a set of gates which serve as Word Lines and facilitate the implementation of a read/write scheme with full random access to individual memory cells.

18. The basic ferroelectric memory group of claim 17, wherein a plurality of individual memory cells (i.e., pairs of field-effect-transistor and ferroelectric-capacitor with one electrode of the capacitor connected to the source of the transistor and the other electrode connected to the drain of the transistor) are stacked along a direction parallel to the plane of the substrate and electrically connected in series.

19. The basic ferroelectric memory group of claim 17, wherein a plurality of individual memory cells (i.e., pairs of field-effect-transistor and ferroelectric-capacitor with one electrode of the capacitor connected to the source of the transistor and the other electrode connected to the drain of the transistor) are stacked along any directions and electrically connected in series.

20. A memory device comprising arrays of the basic ferroelectric memory group of claims 1-13, and 17-19.
